(19) United States
(12) Patent Application Publication
(10) Pub. No.: US 2023/0213695 A1
(43) Pub. Date: Jul. 6, 2023

(54) LAMINATES, POLARIZING PLATES, AND IMAGE DISPLAY DEVICE

(71) Applicant: FUJIFILM Corporation, Tokyo (JP)

(72) Inventors: Kunihiro ATSUMI, Kanagawa (JP); Naoya SHIBATA, Kanagawa (JP)

(73) Assignee: FUJIFILM Corporation, Tokyo (JP)

(21) Appl. No.: 18/181,558

(22) Filed: Mar. 10, 2023

Related U.S. Application Data
(63) Continuation of application No. PCT/JP2021/034712, filed on Sep. 22, 2021.

(30) Foreign Application Priority Data
Sep. 30, 2020 (JP) 2020-164531

(51) Int. Cl. G02B 5/30

(52) U.S. Cl. CPC G02B 5/3016

(57) ABSTRACT

An object of the present invention is to provide a laminate which includes a light absorption anisotropic layer and an optically anisotropic layer and has excellent moisture-heat resistance, and a polarizing plate and an image display device which are formed of the laminate. The laminate of the present invention is a laminate including a light absorption anisotropic layer and an optically anisotropic layer, in which the light absorption anisotropic layer contains an organic dichroic substance, the optically anisotropic layer consists of a liquid crystal layer, an axial direction of an absorption axis of the light absorption anisotropic layer is different from an axial direction of a slow axis of the optically anisotropic layer, and the light absorption anisotropic layer and the optically anisotropic layer are directly laminated.

### CROSS-REFERENCE TO RELATED APPLICATIONS

This application is a Continuation of PCT International Application No. PCT/JP2021/034712 filed on Sep. 22, 2021, which claims priority under 35 U.S.C. § 119(a) to Japanese Patent Application No. 2020-164531 filed on Sep. 30, 2020. The above applications are hereby expressly incorporated by reference, in their entirety, into the present application.

### BACKGROUND OF THE INVENTION

### 1. Field of the Invention

The present invention relates to a laminate, a polarizing plate, and an image display device.

### 2. Description of the Related Art

Optical films such as optical compensation sheets and phase difference films are used in various image display devices from the viewpoints of eliminating image coloration and expanding a viewing angle.

In the related art, a stretched birefringence film has been used as an optical film. However, in recent years, it has been suggested to use an optically anisotropic layer formed of a liquid crystal compound in place of the stretched birefringence film.

Meanwhile, a linear polarizing plate or a circularly polarizing plate is known to be used in an image display device for controlling optical revolution or birefringence in display.

Further, a circularly polarizing plate is also known to be used in an organic electroluminescence (hereinafter, also abbreviated as “EL”) display device for preventing reflection of external light.

In the related art, iodine has been widely used as a dichroic substance in these polarizing plates (polarizers). However, in recent years, a polarizer that uses an organic coloring agent in place of iodine as a dichroic substance has been suggested.

For example, WO2016/121856A describes an optical compensation sheet or a λ/4 wavelength plate, which is formed by bonding a predetermined optically anisotropic layer containing cured liquid crystal molecules is bonded to a base material ([Claim 1], [Claim 7], and [Claim 8]) and also describes an aspect in which a dichroic dye is used as a linear polarizer used in a circularly polarizing plate ([0217]).

### SUMMARY OF THE INVENTION

As a result of examination on a laminate of the circularly polarizing plate and the like described in WO2016/121856A, the present inventors found that in a case where a light absorption anisotropic layer containing an organic dichroic substance and an optically anisotropic layer (for example, a λ/4 wavelength plate) consisting of a liquid crystal layer are laminated by the method (method of bonding layers with a pressure sensitive adhesive layer) described in paragraph [0228] of WO2016/121856A and the obtained laminate is exposed to a high-temperature and high-humidity environment, reticulation occurs and moisture-heat resistance is degraded.

Therefore, an object of the present invention is to provide a laminate which includes a light absorption anisotropic layer and an optically anisotropic layer and has excellent moisture-heat resistance, and a polarizing plate and an image display device which are formed of the laminate.

As a result of intensive examination conducted by the present inventors in order to achieve the above-described object, it was found that a laminate obtained by directly laminating a light absorption anisotropic layer containing an organic dichroic substance and an optically anisotropic layer consisting of a liquid crystal layer has excellent moisture-heat resistance, thereby completing the present invention.

That is, the present inventors found that the above-described object can be achieved by employing the following configurations.

[1] A laminate comprising: a light absorption anisotropic layer; and an optically anisotropic layer, in which the light absorption anisotropic layer contains an organic dichroic substance, the optically anisotropic layer consists of a liquid crystal layer, an axial direction of an absorption axis of the light absorption anisotropic layer is different from an axial direction of a slow axis of the optically anisotropic layer, and the light absorption anisotropic layer and the optically anisotropic layer are directly laminated.

[2] The laminate according to [1], in which the optically anisotropic layer satisfies Expression (I),

0.50<Re(450)/Re(550)<1.00 (I)

in Expression (I), Re (450) represents an in-plane retardation of the optically anisotropic layer at a wavelength of 450 nm, and Re (550) represents an in-plane retardation of the optically anisotropic layer at a wavelength of 550 nm.

[3] The laminate according to [1] or [2], in which the optically anisotropic layer is a layer formed of a polymerizable liquid crystal composition containing a polymerizable liquid crystal compound exhibiting reverse wavelength dispersibility.

[4] The laminate according to any one of [1] to [3], in which a photo-aligned group is unevenly distributed in the light absorption anisotropic layer on an interface side with the optically anisotropic layer.

[5] The laminate according to any one of [1] to [4], in which the optically anisotropic layer includes a first optically anisotropic layer and a second optically anisotropic layer, and the light absorption anisotropic layer, the first optically anisotropic layer, and the second optically anisotropic layer are directly laminated in this order.

[6] The laminate according to [5], in which the first optically anisotropic layer is a positive A-plate.

[7] The laminate according to [5] or [6], in which the second optically anisotropic layer is a positive C-plate.

[8] A laminate comprising: a light absorption anisotropic layer; and an optically anisotropic layer, in which the light absorption anisotropic layer contains an organic dichroic substance, the optically anisotropic layer consists of a liquid crystal layer, a photo-aligned group is unevenly distributed in the light absorption anisotropic layer on an interface side with the optically anisotropic layer, and the light absorption anisotropic layer and the optically anisotropic layer are directly laminated.

[9] A polarizing plate comprising: the laminate according to any one of [1] to [8].

[10] An image display device comprising: the laminate according to any one of [1] to [8]; and the polarizing plate according to [9].

According to the present invention, it is possible to provide a laminate which includes a light absorption anisotropic layer and an optically anisotropic layer and has excellent moisture-heat resistance, and a polarizing plate and an image display device which are formed of the laminate.

### DESCRIPTION OF THE PREFERRED EMBODIMENTS

Hereinafter, the present invention will be described in detail.

The description of constituent requirements described below may be made based on typical embodiments of the present invention, but the present invention is not limited to such embodiments.

In addition, in the present specification, a numerical range shown using “to” indicates a range including numerical values described before and after “to” as a lower limit and an upper limit.

Further, in the present specification, materials corresponding to respective components may be used alone or in combination of two or more kinds thereof. Here, in a case where two or more kinds of substances corresponding to respective components are used in combination, the content of the components indicates the total content of the combined substances unless otherwise specified.

Further, in the present specification, “(meth)acrylate” is a notation representing “acrylate” or “methacrylate”, “(meth)acryl” is a notation representing “acryl” or “methacryl”, and “(meth)acryloyl” is a notation representing “acryloyl” or “methacryloyl”.

Further, the bonding direction of a divalent group (for example, —O—CO—) described in the present specification is not particularly limited. For example, L² represents —O—CO— in a bond of “L¹-L²-L³”, L² may represent *1-O—CO-*2 or *1-CO—O-*2 in a case where the position bonded to the side of L¹ is defined as *1 and the position bonded to the side of L³ is defined as *2.

[Laminate]

A laminate according to a first aspect of the present invention is a laminate formed by directly laminating a light absorption anisotropic layer and an optically anisotropic layer.

Further, in the laminate according to the first aspect of the present invention, the light absorption anisotropic layer contains an organic dichroic substance, and the optically anisotropic layer consists of a liquid crystal layer.

Further, in the laminate according to the first aspect of the present invention, an axial direction of an absorption axis of the light absorption anisotropic layer is different from an axial direction of a slow axis of the optically anisotropic layer, and specifically, an angle between the absorption axis of the light absorption anisotropic layer and the slow axis of the optically anisotropic layer is preferably 45°±10°. Further, in optical design in which a twisted alignment layer is added, the angle between the absorption axis of the light absorption anisotropic layer and the slow axis of the optically anisotropic layer is preferably 13°±10°, 103°±10°, 76°±10°, or 166°±10°.

Here, the term “slow axis” of the optically anisotropic layer denotes a direction in which the in-plane refractive index of the optically anisotropic layer is maximized, and the term “absorption axis” of the light absorption anisotropic layer denotes a direction in which the absorbance is the highest.

Similar to the first aspect, a laminate according to the second aspect of the present invention is a laminate formed by directly laminating a light absorption anisotropic layer and an optically anisotropic layer.

Further, in the laminate according to the second aspect of the present invention, similar to the first aspect, the light absorption anisotropic layer contains an organic dichroic substance, and the optically anisotropic layer consists of a liquid crystal layer.

Furthermore, in the laminate according to the second aspect of the present invention, a photo-aligned group is unevenly distributed in the light absorption anisotropic layer on an interface side with the optically anisotropic layer.

Here, the uneven distribution denotes that the content of the photo-aligned group in a region to a depth of 10% of the optically anisotropic layer in the thickness direction from the interface side of the optically anisotropic layer with the light absorption anisotropic layer is greater than 50% by mass with respect to the total mass of the photo-aligned group contained in the optically anisotropic layer.

In addition, the uneven distribution of the photo-aligned group can be confirmed by, for example, Time-of-Flight Secondary Ion Mass Spectrometry (TOF-SIMS). Further, as the TOF-SIMS method, a method described in “Surface Analysis Technology Selections, Secondary Ion Mass Spectrometry”, edited by Journal of the Surface Science Society of Japan (Maruzen Co., Ltd., published in 1999) can be employed.

Specifically, the analysis is performed by repeating irradiation with ion beams and measurement with TOF-SIMS from the interface side of the optically anisotropic layer with the light absorption anisotropic layer. Further, the irradiation with ion beams and the measurement with TOF-SIMS are performed by repeating a series of operations of performing component analysis in a region of 1 to 2 nm from the surface in the thickness direction (hereinafter, referred to as “surface region”), further entering from 1 nm to several hundreds of nanometers in the thickness direction, and performing component analysis of a next surface region.

Further, the distribution of the photo-aligned group of the optically anisotropic layer in the thickness direction is analyzed by measuring the secondary ion intensity derived from a unit having the photo-aligned group.

Examples of the kind of the ion beams include ion beams using an argon gas cluster ion gun (Ar-GCIB gun).

In the present invention, as described above, a laminate obtained by directly laminating a light absorption anisotropic layer containing an organic dichroic substance and an optically anisotropic layer consisting of a liquid crystal layer has excellent moisture-heat resistance.

The reason for this is not clear, but the present inventors presume as follows.

First, since a laminate obtained by laminating a light absorption anisotropic layer containing an organic dichroic substance and an optically anisotropic layer consisting of a liquid crystal layer via a pressure sensitive adhesive layer is required to provide an alignment layer (photo-alignment layer) on a temporary support in a case of forming a light absorption anisotropic layer, peel the temporary support, and laminate an optically anisotropic layer via a pressure sensitive adhesive layer as described in Comparative Example 1 below, the present inventors presume that the optically anisotropic layer is wrinkled in a high-temperature and high-humidity environment due to a difference in elastic modulus between the light absorption anisotropic layer present in the laminate and the alignment layer which is a layer adjacent to the light absorption anisotropic layer.

Therefore, in the present invention, since the light absorption anisotropic layer and the optically anisotropic layer that are present in the laminate are directly laminated, a difference in elastic modulus between the light absorption anisotropic layer and the optically anisotropic layer which is a layer adjacent to the light absorption anisotropic layer is decreased, and thus generation of wrinkles in the light absorption anisotropic layer in a high-temperature and high-humidity environment is considered to be suppressed.

[Light Absorption Anisotropic Layer]

The light absorption anisotropic layer of the laminate according to the first aspect of the present invention and the laminate according to the second aspect of the present invention (hereinafter, these laminates are collectively referred to as “laminate according to the embodiment of the present invention” in a case where it is not necessary to distinguish between the laminates) is a light absorption anisotropic layer containing an organic dichroic substance.

In the present invention, the thickness of the light absorption anisotropic layer is preferably in a range of 0.1 to 5 μm and more preferably in a range of 0.1 to 3 μm. Particularly, from the viewpoint that the effects of the present invention are significant, the thickness of the light absorption anisotropic layer is preferably 0.8 μm or less and more preferably in a range of 0.1 to 0.8 μm.

In the present invention, it is preferable that the light absorption anisotropic layer is formed of a composition containing an organic dichroic substance (hereinafter, also referred to as “composition for forming a light absorption anisotropic layer”).

<Organic Dichroic Substance>

The organic dichroic substance used in the present invention is not particularly limited.

A dichroic azo coloring agent compound is preferable as the organic dichroic substance, and a dichroic azo coloring agent compound typically used for a so-called coating type polarizer can be used. The dichroic azo coloring agent compound is not particularly limited, and known dichroic azo coloring agent compounds of the related art can be used, but the compounds described below are preferably used.

In the present invention, the dichroic azo coloring agent compound denotes a coloring agent having different absorbances depending on the direction.

The dichroic azo coloring agent compound may or may not exhibit liquid crystallinity.

In a case where the dichroic azo coloring agent compound exhibits liquid crystallinity, the dichroic azo coloring agent compound may exhibit any of nematic liquid crystallinity or smectic liquid crystallinity. The temperature at which the liquid crystal phase is exhibited is preferably in a range of room temperature (approximately 20° C. to 28° C.) to 300° C. and from the viewpoints of handleability and manufacturing suitability, more preferably in a range of 50° C. to 200° C.

In the present invention, from the viewpoint of adjusting the tint, the light absorption anisotropic layer contains preferably at least one coloring agent compound having a maximal absorption wavelength in a wavelength range of 560 to 700 nm (hereinafter, also referred to as “first dichroic azo coloring agent compound”) and at least one coloring agent compound having a maximal absorption wavelength in a wavelength range of 455 nm or greater and less than 560 nm (hereinafter, also referred to as “second dichroic azo coloring agent compound”) and specifically more preferably at least a dichroic azo coloring agent compound represented by Formula (1) and a dichroic azo coloring agent compound represented by Formula (2).

In the present invention, three or more kinds of dichroic azo coloring agent compounds may be used in combination. For example, from the viewpoint of making the color of the light absorption anisotropic layer close to black, it is preferable to use a first dichroic azo coloring agent compound, a second dichroic azo coloring agent compound, and at least one dye compound having a maximum absorption wavelength in a wavelength range of 380 nm or greater and less than 455 nm (preferably in a wavelength range of 380 to 454 nm) (hereinafter, also referred to as “third dichroic azo coloring agent compound”) in combination.

In the present invention, from the viewpoint of further enhancing pressing resistance, it is preferable that the dichroic azo compound contains a crosslinkable group.

Specific examples of the crosslinkable group include a (meth)acryloyl group, an epoxy group, an oxetanyl group, and a styryl group. Among these, a (meth)acryloyl group is preferable.

(First Dichroic Azo Coloring Agent Compound)

It is preferable that the first dichroic azo coloring agent compound is a compound having a chromophore which is a nucleus and a side chain bonded to a terminal of the chromophore.

Specific examples of the chromophore include an aromatic ring group (such as an aromatic hydrocarbon group or an aromatic heterocyclic group) and an azo group. In addition, a structure containing both an aromatic ring group and an azo group is preferable, and a bisazo structure containing an aromatic heterocyclic group (preferably a thienothiazole group) and two azo groups is more preferable.

The side chain is not particularly limited, and examples thereof include a group represented by L3, R2, or L4 in Formula (1).

From the viewpoint adjusting the tint of the polarizer, it is preferable that the first dichroic azo coloring agent compound is a dichroic azo coloring agent compound having a maximum absorption wavelength in a wavelength range of 560 nm or greater and 700 nm or less (more preferably 560 to 650 nm and particularly preferably 560 to 640 nm).

The maximum absorption wavelength (nm) of the dichroic azo coloring agent compound in the present specification is acquired from an ultraviolet visible spectrum in a wavelength range of 380 to 800 nm measured by a spectrophotometer using a solution prepared by dissolving the dichroic azo coloring agent compound in a good solvent.

In the present invention, from the viewpoint of further improving the alignment degree of the light absorption anisotropic layer to be formed, it is preferable that the first dichroic azo coloring agent compound is a compound represented by Formula (1).

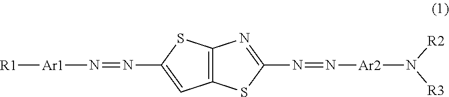

In Formula (1), Ar1 and Ar2 each independently represent a phenylene group which may have a substituent or a naphthylene group which may have a substituent. Among these, a phenylene group is preferable.

In Formula (1), R1 represents a hydrogen atom, a linear or branched alkyl group having 1 to 20 carbon atoms which may have a substituent, an alkoxy group, an alkylthio group, an alkylsulfonyl group, an alkylcarbonyl group, an alkyloxycarbonyl group, an acyloxy group, an alkylcarbonate group, an alkylamino group, an acylamino group, an alkylcarbonylamino group, an alkoxycarbonylamino group, an alkylsulfonylamino group, an alkylsulfamoyl group, an alkylcarbamoyl group, an alkylsulfinyl group, an alkylureido group, an alkylphosphoric acid amide group, an alkylimino group, or an alkylsilyl group.

Further, —CH₂— constituting the alkyl group may be substituted with —O—, —CO—, —C(O)—O—, —O—C(O)—, —Si(CH₃)₂—O—Si(CH₃)₂—, —N(R1′)—, —N(R1′)—CO—, —CO—N(R1′)—, —N(R1′)-C(O) —O—C(O)—N(R1′)—, —N(R1′)-C(O)—N(R1′)—, —CH═CH—, —C≡C—, —N═N—, —C(R1′)=CH—C(O)—, or —O—C(O)—O—.

In a case where R1 represents a group other than a hydrogen atom, the hydrogen atom in each group may be substituted with a halogen atom, a nitro group, a cyano group, —N(R1′)₂, an amino group, —C(R1′)═C(R1′)-NO₂, —C(R1′)═C(R1′)-CN, or —C(R1′)═C(CN)₂.

R1′ represents a hydrogen atom or a linear or branched alkyl group having 1 to 6 carbon atoms. In a case where a plurality of R1 's are present in each group, these may be the same as or different from one another.

In Formula (1), R2 and R3 each independently represent a hydrogen atom, a linear or branched alkyl group having 1 to 20 carbon atoms which may have a substituent, an alkoxy group, an acyl group, an alkyloxycarbonyl group, an alkylamide group, an alkylsulfonyl group, an aryl group, an arylcarbonyl group, an arylsulfonyl group, an aryloxycarbonyl group, or an arylamide group.

Further, —CH₂— constituting the alkyl group may be substituted with —O—, —S—, —C(O)—, —C(O)—O—, —O—C(O)—, —C(O)—S—, —S—C(O)—, —Si(CH₃)₂—O—Si(CH₃)₂—, —NR2′—, —NR2′-CO—, —CO— NR2′—, —NR2′-C(O)—O—, —O—C(O)—NR2′—, —NR2′-C(O)—NR2′—, —CH═CH—, —C≡C—, —N═N—, —C(R2′)=CH—C(O)—, or —O—C(O)—O—.

In a case where R2 and R3 represent a group other than a hydrogen atom, the hydrogen atom of each group may be substituted with a halogen atom, a nitro group, a cyano group, a —OH group, —N(R2′)₂, an amino group, —C(R2′)═C(R2′)-NO₂, —C(R2′)═C(R2′)-CN, or —C(R2′)═C(CN)₂.

R2′ represents a hydrogen atom or a linear or branched alkyl group having 1 to 6 carbon atoms. In a case where a plurality of R2's are present in each group, these may be the same as or different from one another.

R2 and R3 may be bonded to each other to form a ring, or R2 or R3 may be bonded to Ar2 to form a ring.

From the viewpoint of the light resistance, it is preferable that R1 represents an electron-withdrawing group and that R2 and R3 represent a group having a low electron-donating property.

Specific examples of such groups as R1 include an alkylsulfonyl group, an alkylcarbonyl group, an alkyloxycarbonyl group, an acyloxy group, an alkylsulfonylamino group, an alkylsulfamoyl group, an alkylsulfinyl group, and an alkylureido group, and examples of such groups as R2 and R3 include groups having the following structures. In addition, the groups having the following structures are shown in the form having a nitrogen atom to which R2 and R3 are bonded in Formula (1).

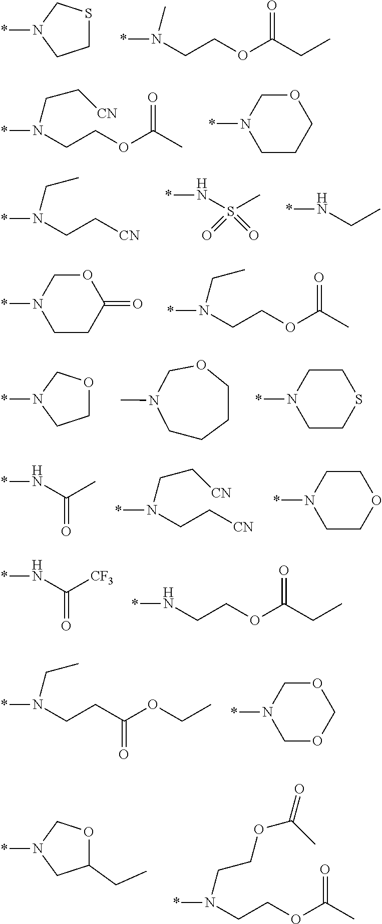

Specific examples of the first dichroic azo coloring agent compound are shown below, but the present invention is not limited thereto.

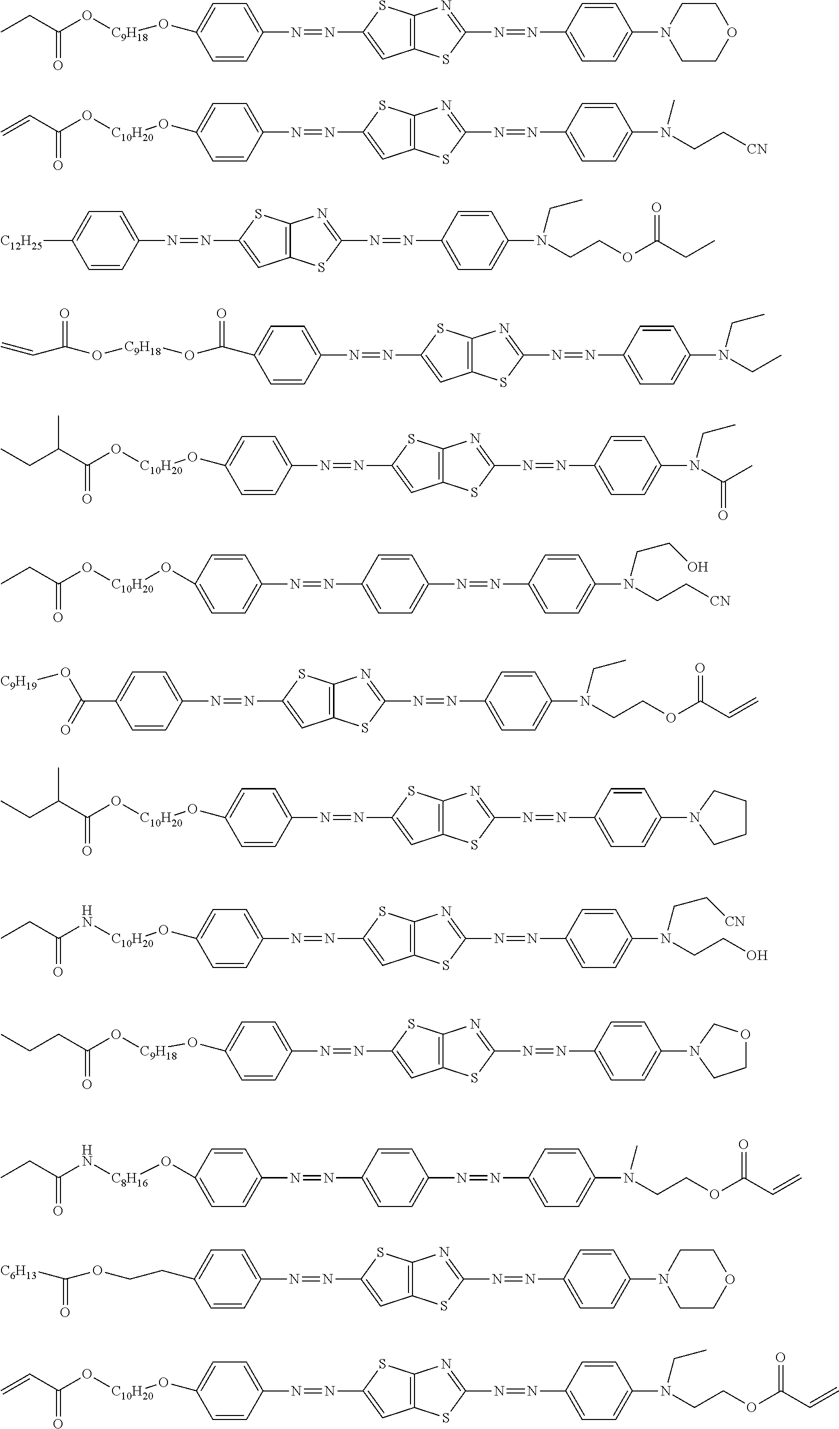

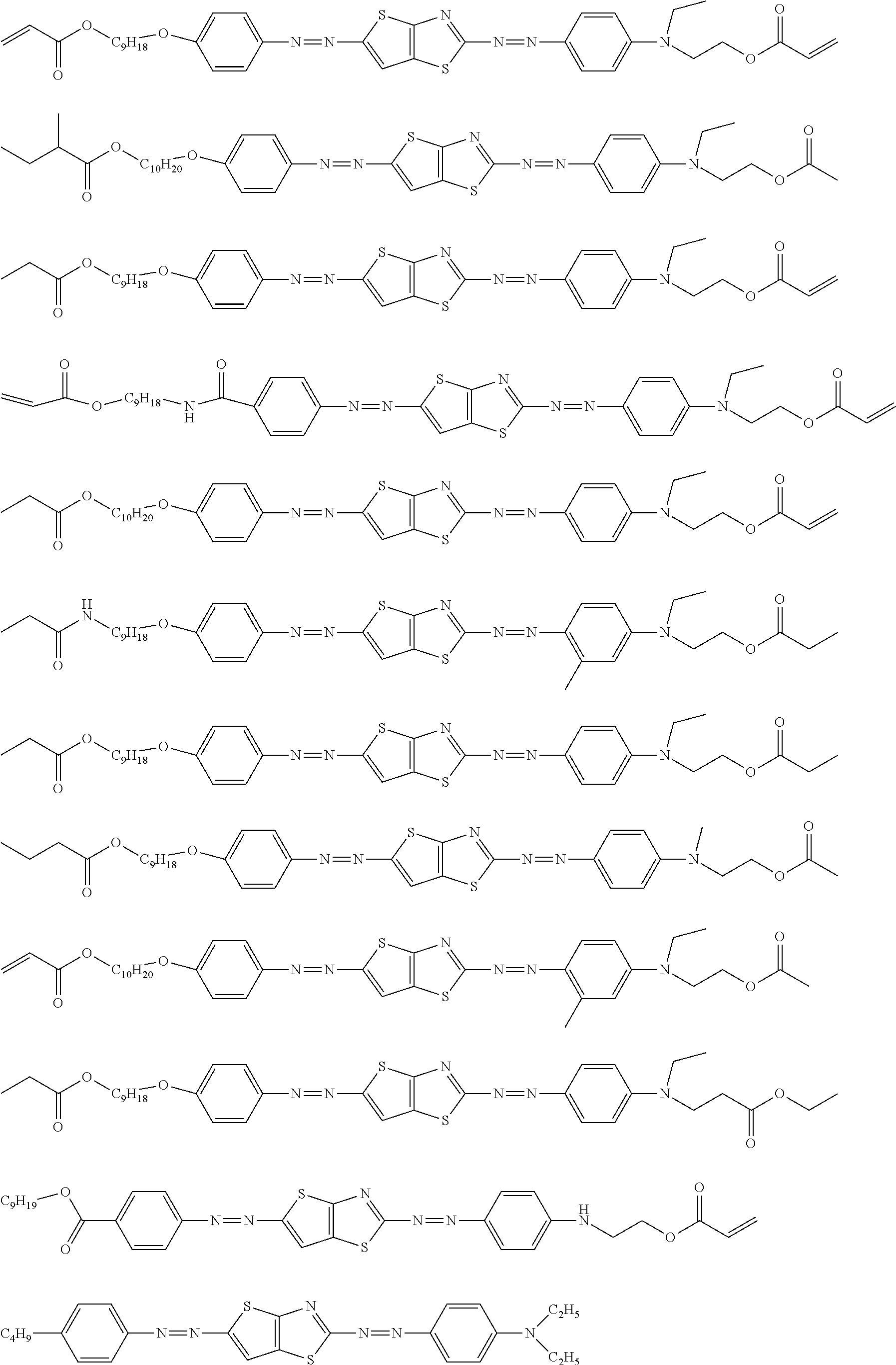

(Second Dichroic Azo Coloring Agent Compound)

The second dichroic azo coloring agent compound is a compound different from the first dichroic azo coloring agent compound, and specifically, the chemical structure thereof is different from that of the first dichroic azo coloring agent compound.

It is preferable that the second dichroic azo coloring agent compound is a compound having a chromophore which is a nucleus of a dichroic azo coloring agent compound and a side chain bonded to a terminal of the chromophore.

Specific examples of the chromophore include an aromatic ring group (such as an aromatic hydrocarbon group or an aromatic heterocyclic group) and an azo group. In addition, a structure containing both an aromatic hydrocarbon group and an azo group is preferable, and a bisazo or trisazo structure containing an aromatic hydrocarbon group and two or three azo groups is more preferable.

The side chain is not particularly limited, and examples thereof include a group represented by R4, R5, or R6 in Formula (2).

The second dichroic azo coloring agent compound is a dichroic azo coloring agent compound having a maximum absorption wavelength in a wavelength range of 455 nm or greater and less than 560 nm, preferably a dichroic azo coloring agent compound having a maximum absorption wavelength in a wavelength range of 455 to 555 nm, and more preferably a dichroic azo coloring agent compound having a maximum absorption wavelength in a wavelength range of 455 to 550 nm from the viewpoint of adjusting the tint of the polarizer.

In particular, the tint of the polarizer is easily adjusted by using a first dichroic azo coloring agent compound having a maximal absorption wavelength of 560 to 700 nm and a second dichroic azo coloring agent compound having a maximal absorption wavelength of 455 nm or greater and less than 560 nm.

From the viewpoint of further improving the alignment degree of the polarizer, it is preferable that the second dichroic azo coloring agent compound is a compound represented by Formula (2).

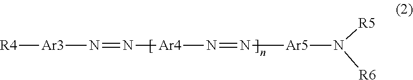

In Formula (2), n represents 1 or 2.

In Formula (2), Ar3, Ar4, and Ar5 each independently represent a phenylene group which may have a substituent, a naphthylene group which may have a substituent, or a heterocyclic group which may have a substituent.

The heterocyclic group may be aromatic or non-aromatic.

The atoms other than carbon constituting the aromatic heterocyclic group include a nitrogen atom, a sulfur atom, and an oxygen atom. In a case where the aromatic heterocyclic group has a plurality of atoms constituting a ring other than carbon, these may be the same as or different from each other.

Specific examples of the aromatic heterocyclic group include a pyridylene group (pyridine-diyl group), a pyridazine-diyl group, an imidazole-diyl group, a thienylene group (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

In Formula (2), R4 has the same definition as that for R1 in Formula (1).

In Formula (2), R5 and R6 each have the same definition as that for R2 and R3 in Formula (1).

From the viewpoint of the light resistance, it is preferable that R4 represents an electron-withdrawing group and that R5 and R6 represent a group having a low electron-donating property.

Among such groups, specific examples of the electron-withdrawing group as R4 are the same as the specific examples of the electron-withdrawing group as R1, and specific examples of the group having a low electron-donating property as R5 and R6 are the same as the specific examples of the group having a low electron-donating property as R2 and R3.

Specific examples of the second dichroic azo coloring agent compound are shown below, but the present invention is not limited thereto.

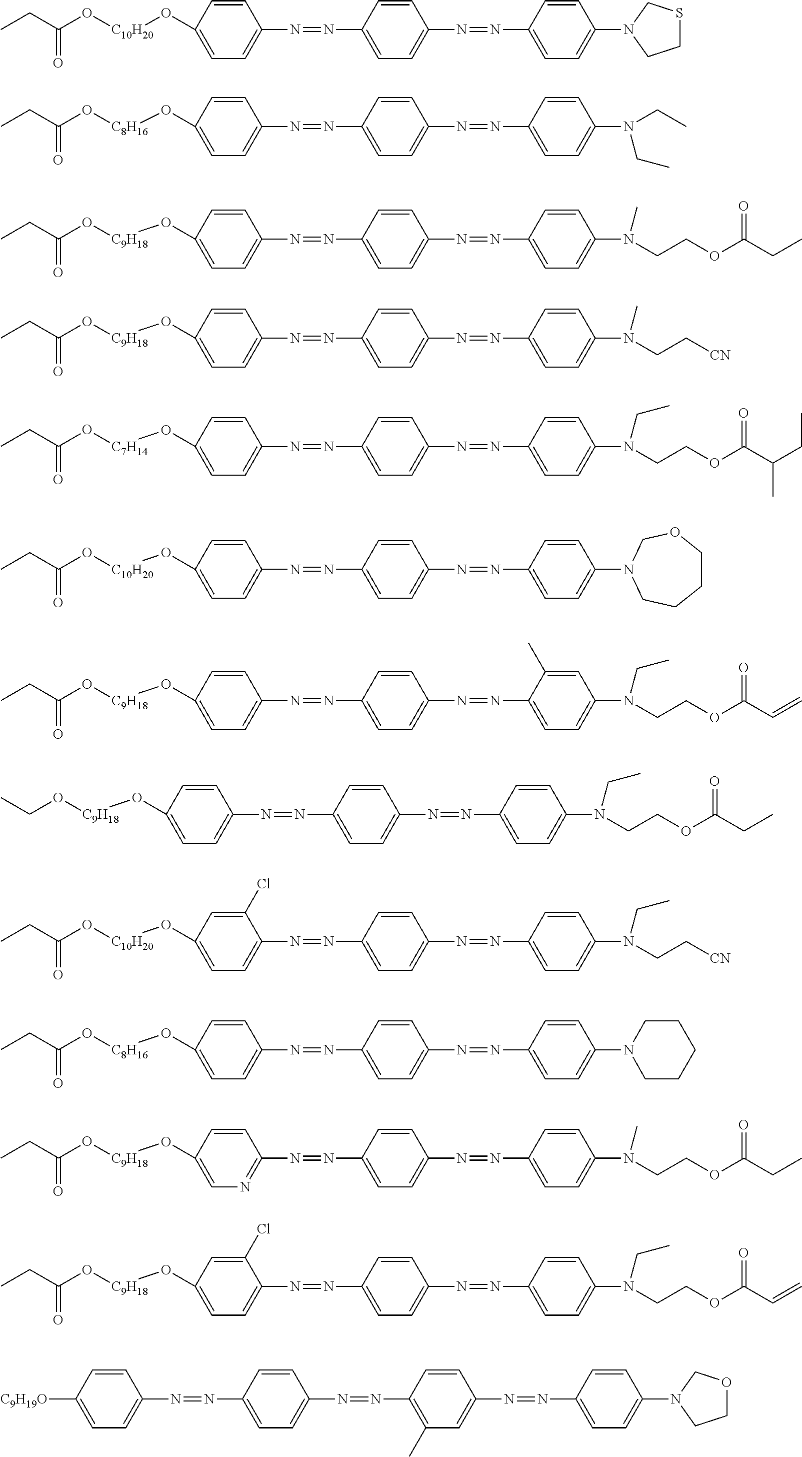

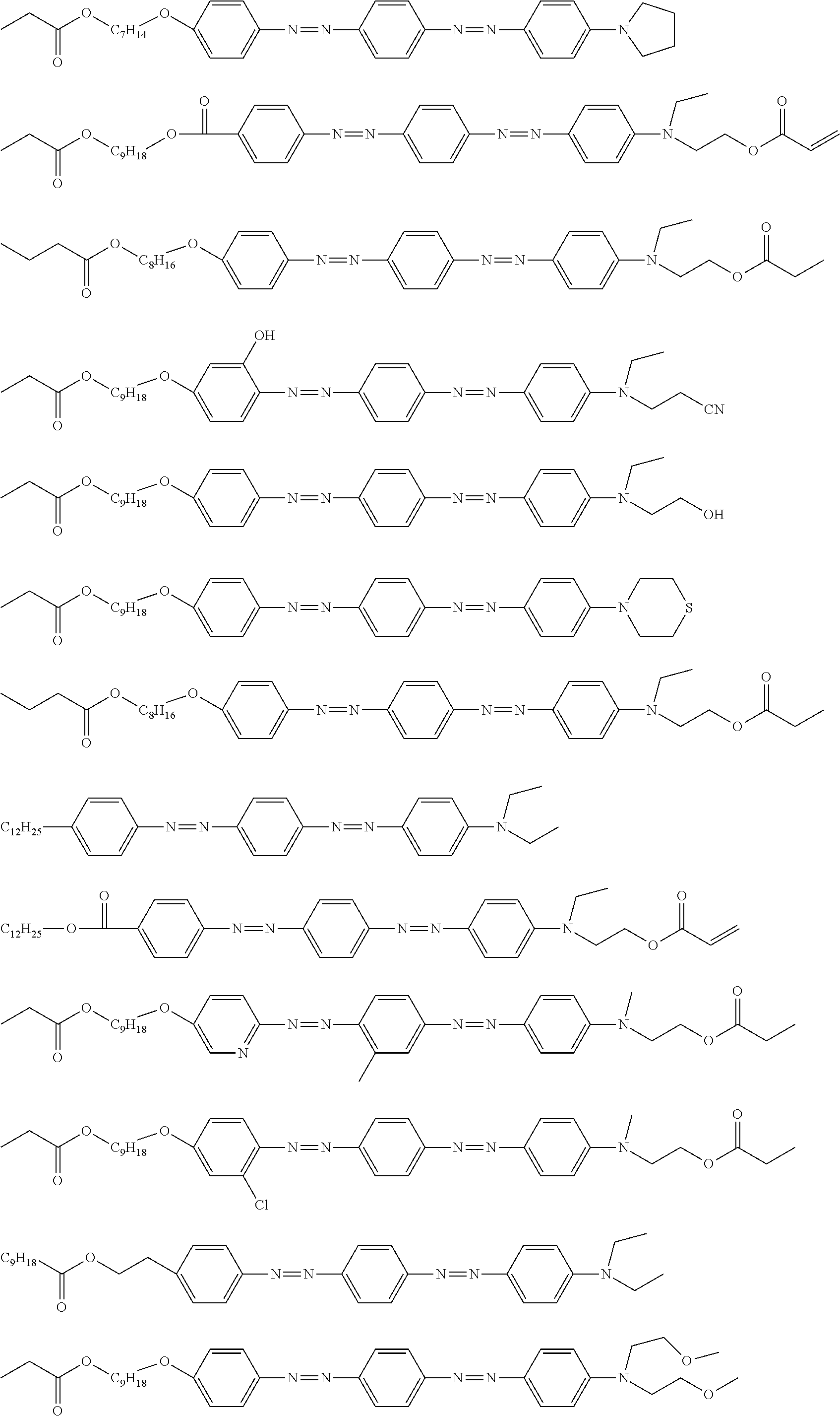

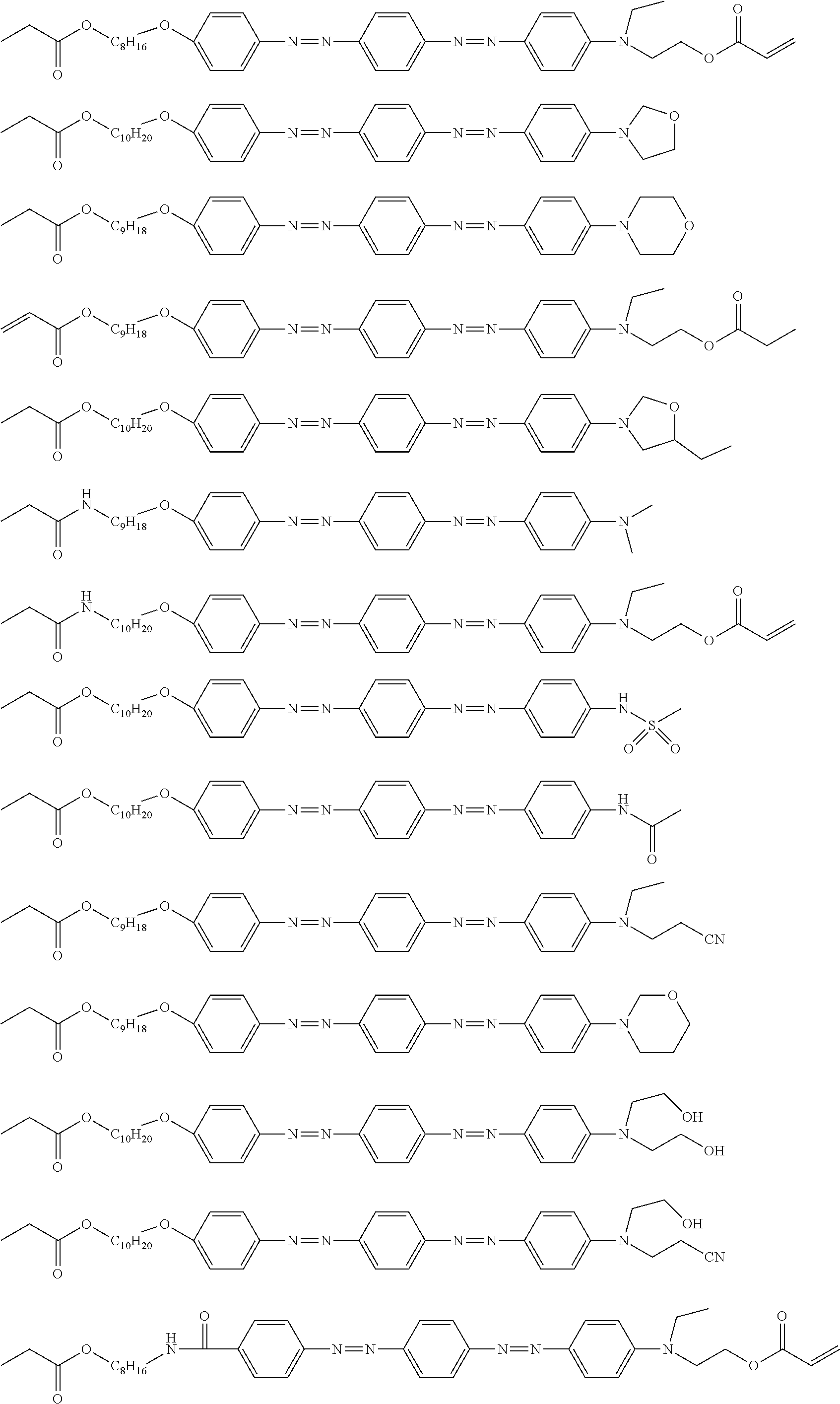

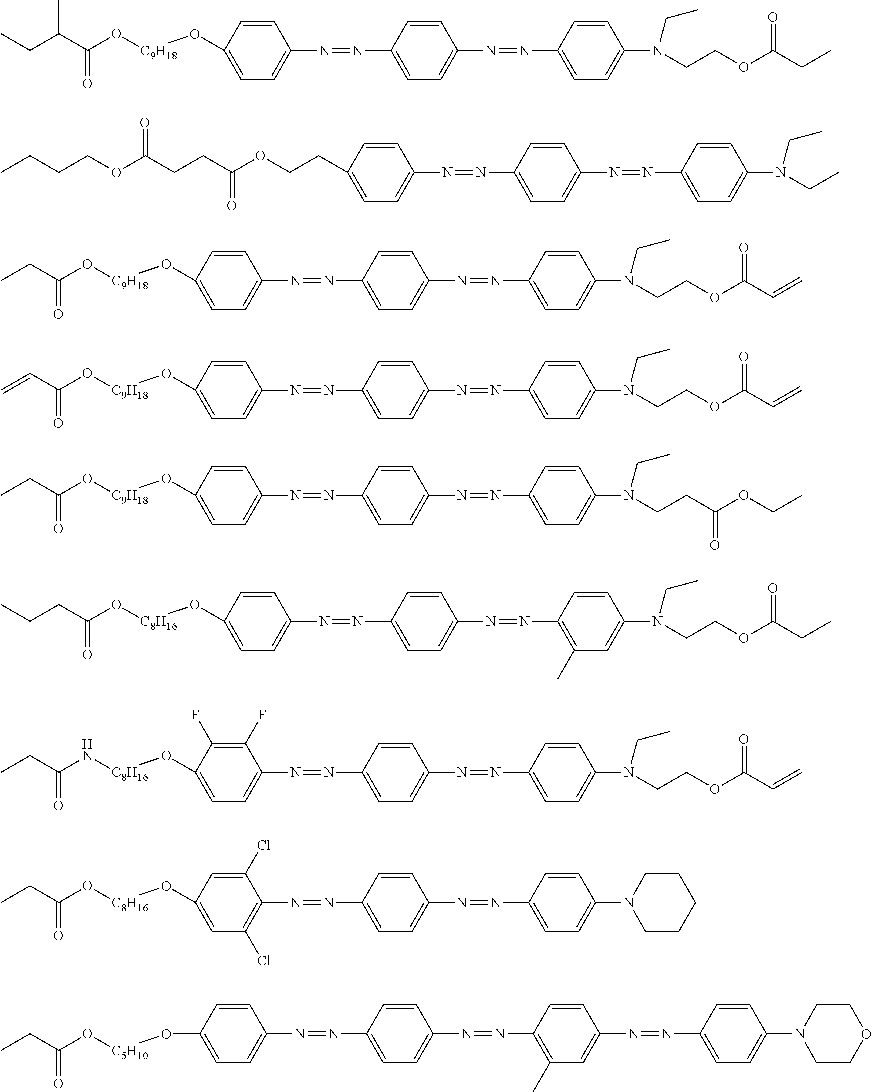

(Third Dichroic Azo Coloring Agent Compound)

The third dichroic azo coloring agent compound is a dichroic azo coloring agent compound other than the first dichroic azo coloring agent compound and the second dichroic azo coloring agent compound, and specifically, the chemical structure thereof is different from those of the first dichroic azo coloring agent compound and the second dichroic azo coloring agent compound. In a case where the light absorption anisotropic layer contains the third dichroic azo coloring agent compound, there is an advantage that the tint of the light absorption anisotropic layer is easily adjusted.

The maximum absorption wavelength of the third dichroic azo coloring agent compound is 380 nm or greater and less than 455 nm and preferably in a range of 385 to 454 nm.

Specific examples of the third dichroic azo coloring agent compound include compounds other than the first dichroic azo coloring agent compound and the second dichroic azo coloring agent compound among the compounds represented by Formula (1) described in WO2017/195833A.

Specific examples of the third dichroic coloring agent compound are shown below, but the present invention is not limited thereto. In the following specific examples, n represents an integer of 1 to 10.

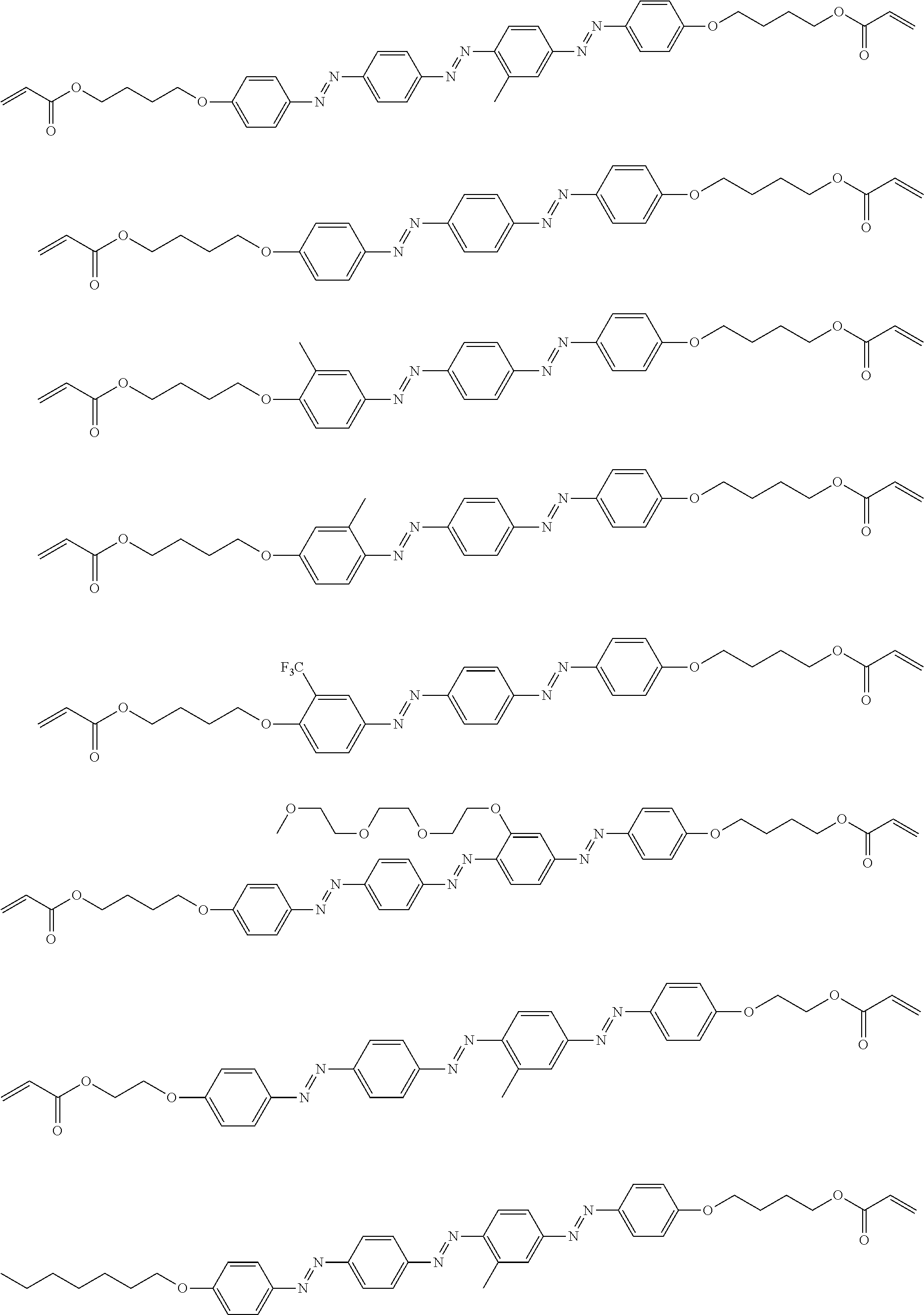

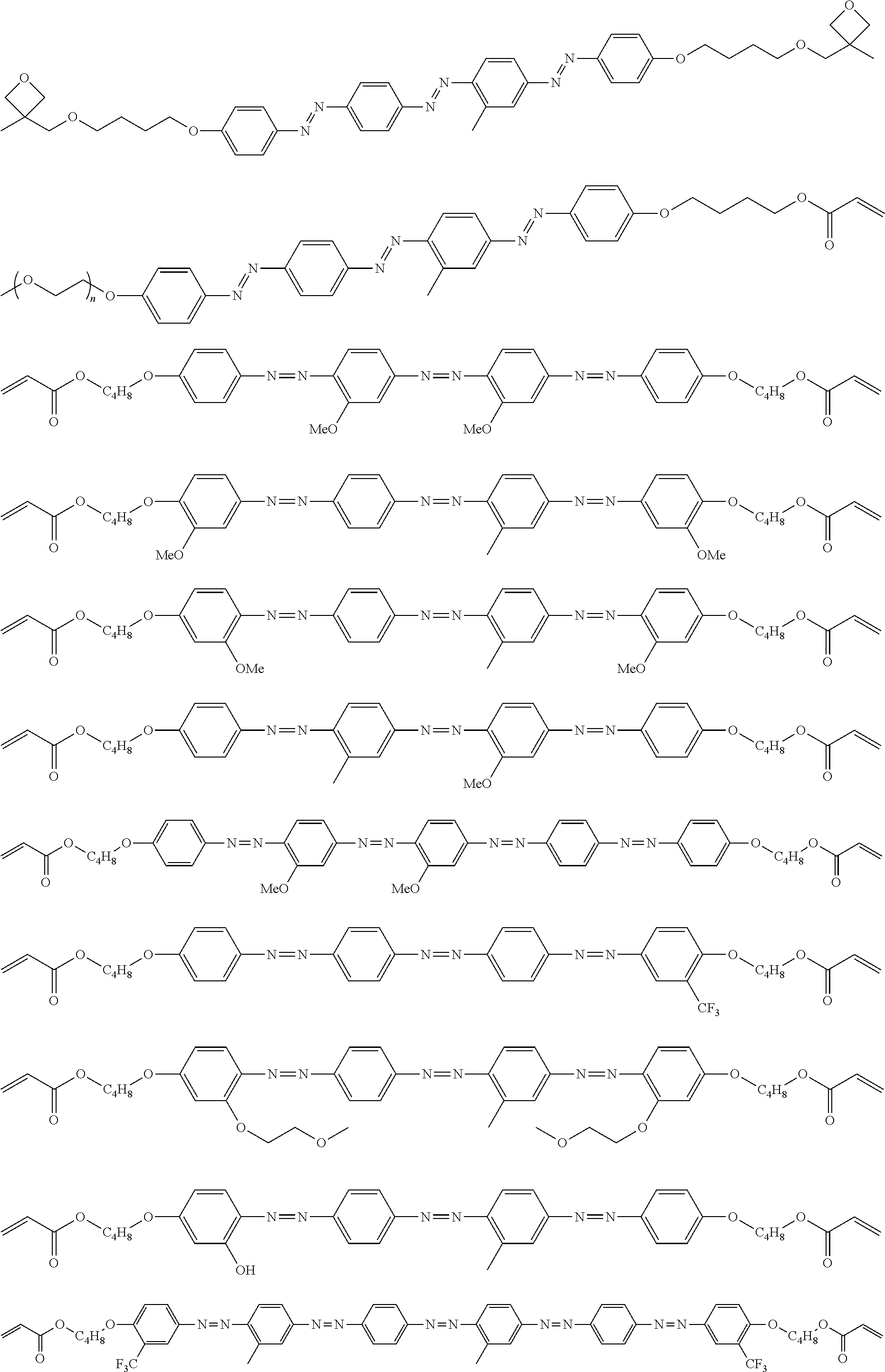

(Content of Dichroic Azo Coloring Agent Compound)

The content of the dichroic azo coloring agent compound is preferably in a range of 15% to 30% by mass, more preferably in a range of 18% to 28% by mass, and still more preferably in a range of 20% to 26% by mass with respect to the total mass of the solid content of the light absorption anisotropic layer. In a case where the content of the dichroic azo coloring agent compound is in the above-described ranges, a light absorption anisotropic layer having a high alignment degree can be obtained even in a case where the light absorption anisotropic layer is formed into a thin film. Therefore, a light absorption anisotropic layer having excellent flexibility is likely to be obtained. Further, in a case where the content thereof is greater than 30% by mass, it is difficult to suppress internal reflection by a refractive index adjusting layer.

The content of the first dichroic azo coloring agent compound is preferably in a range of 40 to 90 parts by mass and more preferably in a range of 45 to 75 parts by mass with respect to 100 parts by mass of the total content of the dichroic azo coloring agent substance in the composition for forming a light absorption anisotropic layer.

The content of the second dichroic azo coloring agent compound is preferably in a range of 6 to 50 parts by mass and more preferably in a range of 8 to 35 parts by mass with respect to 100 parts by mass of the total content of the dichroic azo coloring agent compound in the composition for forming a light absorption anisotropic layer.

The content of the third dichroic azo coloring agent compound is preferably in a range of 3 to 35 parts by mass and more preferably in a range of 5 to 30 parts by mass with respect to 100 parts by mass of the content of the dichroic azo coloring agent compound in the composition for forming a light absorption anisotropic layer.

The content ratio between the first dichroic azo coloring agent compound, the second dichroic azo coloring agent compound, and the third dichroic azo coloring agent compound used as necessary can be optionally set in order to adjust the tint of the light absorption anisotropic layer. Here, the content ratio of the second dichroic azo coloring agent compound to the first dichroic azo coloring agent compound (second dichroic azo coloring agent compound/first dichroic azo coloring agent compound) is preferably in a range of 0.1 to 10, more preferably in a range of 0.2 to 5, and still more preferably in a range of 0.3 to 0.8 in terms of moles.

<Liquid Crystal Compound>

The composition for forming a light absorption anisotropic layer may contain a liquid crystal compound. In a case where the composition contains a liquid crystal compound, the organic dichroic substance (particularly, the dichroic azo coloring agent compound) can be aligned with a high alignment degree while the precipitation of the organic dichroic substance (particularly, the dichroic azo coloring agent compound) is suppressed.

The liquid crystal compound is a liquid crystal compound that does not exhibit dichroism.

As the liquid crystal compound, both a low-molecular-weight liquid crystal compound and a polymer liquid crystal compound can be used, but a polymer liquid crystal compound is more preferable from the viewpoint of obtaining a high alignment degree. Here, the term “low-molecular-weight liquid crystal compound” denotes a liquid crystal compound having no repeating units in the chemical structure. Here, the term “polymer liquid crystal compound” denotes a liquid crystal compound having a repeating unit in the chemical structure.

Examples of the low-molecular-weight liquid crystal compound include liquid crystal compounds described in JP2013-228706A.

Examples of the polymer liquid crystal compound include thermotropic liquid crystal polymers described in JP2011-237513A and WO2019/131943A. Further, the polymer liquid crystal compound may contain a crosslinkable group (such as an acryloyl group or a methacryloyl group) at a terminal.

The liquid crystal compound may be used alone or in combination of two or more kinds thereof.

The content of the liquid crystal compound is preferably in a range of 100 to 600 parts by mass, more preferably in a range of 200 to 450 parts by mass, and still more preferably in a range of 250 to 400 parts by mass with respect to 100 parts by mass of the content of the organic dichroic substance in the composition for forming a light absorption anisotropic layer. In a case where the content of the liquid crystal compound is in the above-described ranges, the alignment degree of the light absorption anisotropic layer is further improved.

(Weight-Average Molecular Weight)

From the viewpoint that the alignment degree of the light absorption anisotropic layer is more excellent, the weight-average molecular weight (Mw) of the polymer liquid crystal compound is preferably in a range of 1000 to 500000 and more preferably in a range of 2000 to 300000. In a case where the Mw of the polymer liquid crystal compound is in the above-described ranges, the polymer liquid crystal compound is easily handled.

In particular, from the viewpoint of suppressing cracking during the coating, the weight-average molecular weight (Mw) of the polymer liquid crystal compound is preferably 10000 or greater and more preferably in a range of 10000 to 300000.

In addition, from the viewpoint of the temperature latitude of the alignment degree, the weight-average molecular weight (Mw) of the polymer liquid crystal compound is preferably less than 10000 and more preferably 2000 or greater and less than 10000.

Here, the weight-average molecular weight in the present invention is a value measured by gel permeation chromatography (GPC).
Solvent (eluent): N-methylpyrrolidone
Equipment name: TOSOH HLC-8220GPC
Column: Connect and use three of TOSOH TSKgel Super AWM-H (6 mm×15 cm)
Column temperature: 25° C.
Sample concentration: 0.1% by mass
Flow rate: 0.35 mL/min
Calibration curve: TSK standard polystyrene (manufactured by TOSOH Corporation), calibration curves of 7 samples with Mw of 2800000 to 1050 (Mw/Mn=1.03 to 1.06) are used.

[Optically Anisotropic Layer]

The optically anisotropic layer of the laminate according to the embodiment of the present invention is an optically anisotropic layer consisting of a liquid crystal layer.

In the present invention, from the viewpoint of enhancing antireflection performance, it is preferable that the optically anisotropic layer satisfies Expression (I).

0.50<Re(450)/Re(550)<1.00 (I)

Here, in Formula (I), Re (450) represents an in-plane retardation of the optically anisotropic layer at a wavelength of 450 nm, and Re (550) represents an in-plane retardation of the optically anisotropic layer at a wavelength of 550 nm. In the present specification, the measurement wavelength is set to 550 nm in a case where the measurement wavelength of the retardation is not specified.

Further, the values of the in-plane retardation and the retardation in the thickness direction denotes values measured using light having the measurement wavelength with AxoScan OPMF-1 (manufactured by Opto Science, Inc.).

Specifically, the slow axis direction)(°), “Re (λ)=R0(λ)”, and “Rth (λ)=((nx+ny)/2−nz)×d” are calculated by inputting the average refractive index ((Nx+Ny+Nz)/3) and the film thickness (d(μm)) to AxoScan OPMF-1.

Further, R0 (λ) is displayed as a numerical value calculated by AxoScan OPMF-1 and denotes Re (λ).

Further, in regard to the aspect in which the light absorption anisotropic layer and the optically anisotropic layer are directly laminated, in the laminate according to the first aspect of the present invention, an aspect in which the surface of the light absorption anisotropic layer is subjected to a rubbing treatment and the optically anisotropic layer is laminated may be employed, and an aspect in which the optically anisotropic layer is laminated in a state where the photo-aligned group is unevenly distributed in the light absorption anisotropic layer on the interface side with the optically anisotropic layer is preferable from the viewpoint of easily directly laminating the light absorption anisotropic layer and the optically anisotropic layer.

In addition, examples of the above-described photo-aligned group include those exemplified as the photo-aligned group of a photo-aligned polymer described below.

In the present invention, it is preferable that the optically anisotropic layer is formed of a liquid crystal composition containing a liquid crystal compound (hereinafter, also referred to as “composition for forming an optically anisotropic layer”).

In the optically anisotropic layer that is in direct contact with the light absorption anisotropic layer, it is preferable that the molecules of the liquid crystal compound are fixed in a state of a smectic phase or a nematic phase in homogeneous alignment.

<Liquid Crystal Compound>

The liquid crystal compound contained in the composition for forming an optically anisotropic layer is a liquid crystal compound containing a polymerizable group.

Typically, the liquid crystal compound can be classified into a rod type compound and a disk type compound depending on the shape thereof. Further, the above-described types of compounds respectively include a low-molecular-weight type compound and a polymer type compound. The polymer indicates a compound having a degree of polymerization of 100 or greater (Polymer Physics and Phase Transition Dynamics, written by Masao Doi, p. 2, Iwanami Shoten, Publishers, 1992).

In the present invention, any liquid crystal compound can also be used, but it is preferable to use a rod-like liquid crystal compound or a discotic liquid crystal compound and more preferable to use a rod-like liquid crystal compound.

In the present invention, from the viewpoint of fixing the above-described liquid crystal compound, a liquid crystal compound containing a polymerizable group is used, and it is more preferable that the liquid crystal compound contains two or more polymerizable groups in one molecule. Further, in a case where a mixture of two or more kinds of liquid crystal compounds is used, it is preferable that at least one liquid crystal compound contains two or more polymerizable groups in one molecule. Further, the liquid crystal compound is not required to exhibit liquid crystallinity after the compound is fixed by polymerization.

Further, the kind of the polymerizable group is not particularly limited, but a functional group capable of carrying out the addition polymerization reaction is preferable, and a polymerizable ethylenically unsaturated group or a ring polymerizable group is preferable. More specifically, preferred examples thereof include a (meth)acryloyl group, a vinyl group, a styryl group, and an allyl group. Among these, a (meth)acryloyl group is more preferable.

For example, those described in claim 1 of JP1999-513019A (JP-H11-513019A) and paragraphs [0026] to [0098] of JP2005-289980A can be preferably used as the rod-like liquid crystal compound, and those described in paragraphs [0020] to [0067] of JP2007-108732A and paragraphs [0013] to [0108] of JP2010-244038A can be preferably used as the discotic liquid crystal compound, but the present invention is not limited thereto.

Further, in the present invention, a reverse wavelength dispersion liquid crystal compound can be used as the liquid crystal compound.

In the present specification, the liquid crystal compound having “reverse wavelength dispersibility” denotes that in a case where the in-plane retardation (Re) value of a phase difference film prepared using this liquid crystal compound is measured at a specific wavelength (visible light range), the Re value does not change or increases as the measurement wavelength increases.

Further, the reverse wavelength dispersion liquid crystal compound is not particularly limited as long as a film having reverse wavelength dispersibility can be formed as described above, and examples thereof include the compound represented by General Formula (1) described in JP2010-084032A (particularly the compound described in paragraphs [0067] to) [0073]), the compound represented by General Formula (II) described in JP2016-053709A (particularly the compound described in paragraphs [0036] to [0043]), and the compound represented by General Formula described in JP2016-081035A (particularly the compound described in paragraphs [0043] to [0055]).

<Photo-Aligned Polymer>

The composition for forming an optically anisotropic layer contains preferably a photo-aligned polymer that has a repeating unit containing a photo-aligned group from the viewpoint of easily directly laminating the light absorption anisotropic layer and the optically anisotropic layer and more preferably a photo-aligned polymer that has a repeating unit containing a photo-aligned group and a repeating unit containing a cleavage group which is decomposed due to an action of at least one selected from the group consisting of light, heat, an acid, and a base and generates a polar group (hereinafter, also referred to as “cleavage group-containing photo-aligned polymer”) from the viewpoint of more easily directly laminating the light absorption anisotropic layer and the optically anisotropic layer.

(Repeating Unit Containing Photo-Aligned Group)

Examples of the repeating unit containing a photo-aligned group of the photo-aligned polymer include a repeating unit represented by Formula (A) (hereinafter, also referred to as “repeating unit A”).

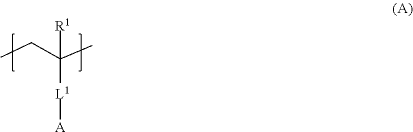

In Formula (A), R¹ represents a hydrogen atom or a substituent, L¹ represents a divalent linking group, and A represents a photo-aligned group.

Next, the hydrogen atom or the substituent represented by R¹ in Formula (A) will be described.

In Formula (A), as the substituent represented by an aspect of R′, a halogen atom, a linear alkyl group having 1 to 20 carbon atoms, a branched or cyclic alkyl group having 3 to 20 carbon atoms, a linear halogenated alkyl group having 1 to 20 carbon atoms, an alkoxy group having 1 to 20 carbon atoms, an aryl group having 6 to 20 carbon atoms, an aryloxy group having 6 to 20 carbon atoms, a cyano group, or an amino group is preferable.

Next, the divalent linking group represented by L¹ in Formula (A) will be described.

From the viewpoint of enhancing the aligning properties of the light absorption anisotropic layer, as the divalent linking group, a divalent linking group obtained by combining at least two or more groups selected from the group consisting of a linear alkylene group having 1 to 18 carbon atoms which may have a substituent, a branched or cyclic alkylene group having 3 to 18 carbon atoms which may have a substituent, an arylene group having 6 to 12 carbon atoms which may have a substituent, an ether group (—O—), a carbonyl group (—C(═O)—), and an imino group (—NH—) which may have a substituent is preferable.

Here, examples of the substituent that the alkylene group, the arylene group, and the imino group may have include a halogen atom, an alkyl group, an alkoxy group, an aryl group, an aryloxy group, a cyano group, a carboxy group, an alkoxycarbonyl group, and a hydroxyl group.

Examples of the halogen atom include a fluorine atom, a chlorine atom, a bromine atom, and an iodine atom. Among these, a fluorine atom and a chlorine atom are preferable.

Further, the number of carbon atoms of the alkyl group is preferably in a range of 1 to 18, the number of carbon atoms of the alkoxy group is preferably in a range of 1 to 18, and the number of carbon atoms of the aryl group is preferably in a range of 6 to 12.

In the present invention, from the viewpoint of enhancing the aligning properties of the light absorption anisotropic layer described above, L¹ in Formula (A) represents preferably a divalent linking group having a cycloalkane ring and more preferably a divalent linking group having a nitrogen atom and a cycloalkane ring.

In the preferred embodiment, some carbon atoms constituting the cycloalkane ring may be substituted with a heteroatom selected from the group consisting of nitrogen, oxygen, and sulfur. Further, in a case where some carbon atoms constituting the cycloalkane ring are substituted with nitrogen atoms, the divalent linking group may not have a nitrogen atom separately from the cycloalkane ring.

Further, a cycloalkane ring having 6 or more carbon atoms is preferable as the cycloalkane ring, and specific examples thereof include a cyclohexane ring, a cycloheptane ring, a cyclooctane ring, a cyclododecane ring, and a cyclodocosane ring.

In the present invention, from the viewpoint of further enhancing the aligning properties of the light absorption anisotropic layer, it is preferable that L¹ in Formula (A) represents a divalent linking group represented by any of Formulae (3) to (12).

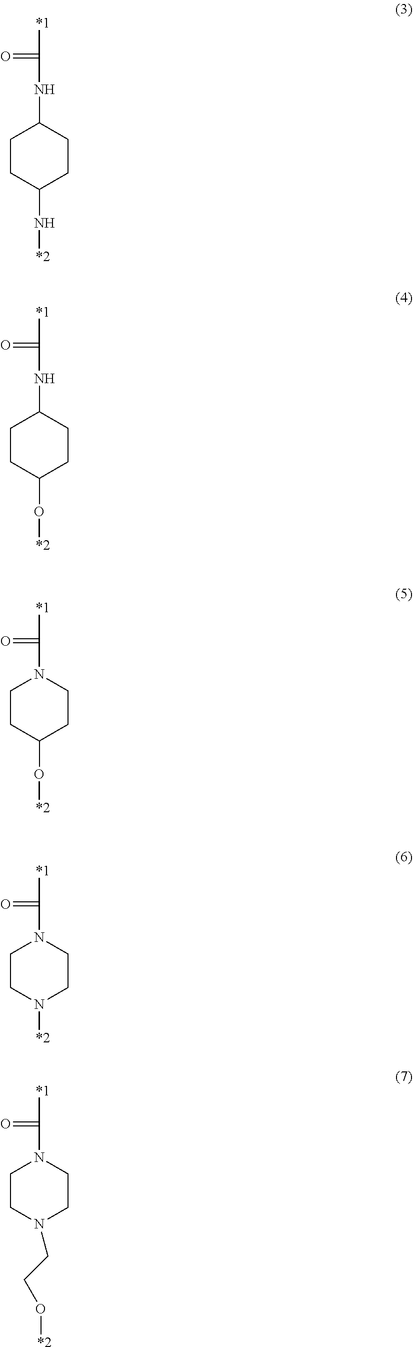

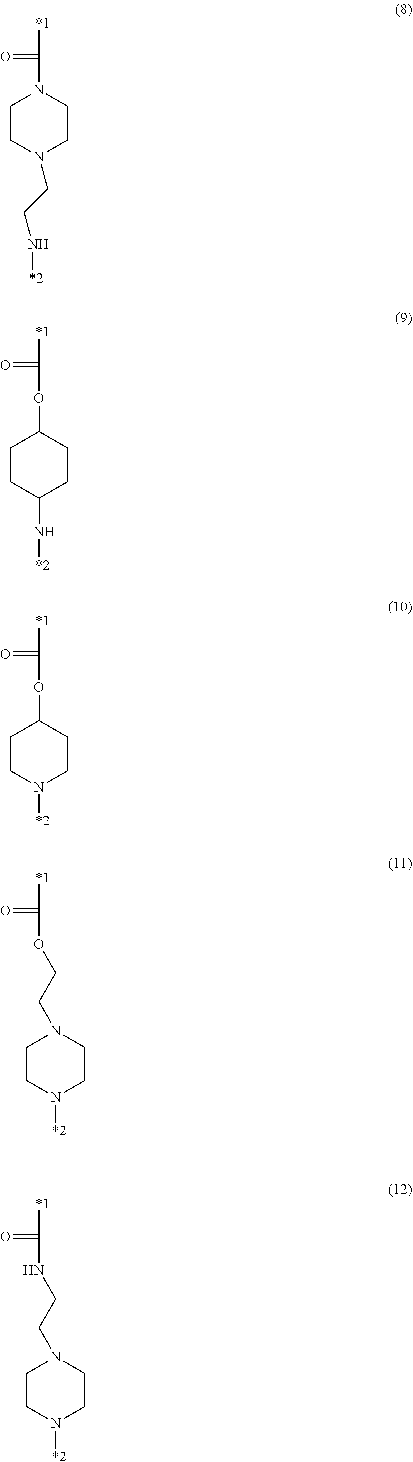

In Formulae (3) to (12), *1 represents a bonding position between R′ in Formula (A) and a carbon atom bonded thereto, and *2 represents a bonding position with respect to A in Formula (A).

Among the divalent linking groups represented by any of Formulae (3) to (12), a divalent linking group represented by any of Formulae (4), (5), (9), and (10) is preferable from the viewpoint of enhancing the balance between the solubility in a solvent used for forming the optically anisotropic layer and the solvent resistance of the optically anisotropic layer to be obtained.

Next, a photo-aligned group represented by A in Formula (A) will be described.

From the viewpoint of enhancing the thermal stability and the chemical stability of a monomer containing a photo-aligned group, a group in which at least one of dimerization or isomerization occurs due to an action of light is preferable as the photo-aligned group.

Specific suitable examples of the group that is dimerized due to an action of light include a group having a skeleton of at least one derivative selected from the group consisting of a cinnamic acid derivative, a coumarin derivative, a chalcone derivative, a maleimide derivative, and a benzophenone derivative.

In addition, specific suitable examples of the group that is isomerized due to an action of light include a group having a skeleton of at least one compound selected from the group consisting of an azobenzene compound, a stilbene compound, a spiropyran compound, a cinnamic acid compound, and a hydrazono-3-ketoester compound.

Among the above-described photo-aligned groups, a group having a skeleton of at least one derivative or compound selected from the group consisting of a cinnamic acid derivative, a coumarin derivative, a chalcone derivative, a maleimide derivative, an azobenzene compound, a stilbene compound, and a spiropyran compound is preferable. Among these, from the viewpoint of enhancing the aligning properties of the light absorption anisotropic layer described above, a group having a skeleton of a cinnamic acid derivative or an azobenzene compound is more preferable, and a group having a skeleton of a cinnamic acid derivative (hereinafter, also referred to as “cinnamoyl group”) is still more preferable.

In the present invention, it is preferable that the photo-aligned group is the photo-aligned group described in paragraphs [0036] to [0040] of WO2020/179864A.

Further, examples of the repeating unit A represented by Formula (A) include the repeating units described in paragraphs [0041] to [0049] of WO2020/179864A.

The content of the repeating unit containing a photo-aligned group in the photo-aligned polymer is not particularly limited, but is preferably in a range of 3% to 40% by mole, more preferably in a range of 6% to 30% by mole, and still more preferably in a range of 10% to 25% by mole with respect to all repeating units of the photo-aligned polymer from the viewpoint of enhancing the aligning properties of the light absorption anisotropic layer described above.

(Repeating Unit Containing Cleavage Group)

As the repeating unit containing a cleavage group in the cleavage group-containing photo-aligned polymer, a repeating unit which contains a cleavage group that is decomposed due to an action of at least one kind selected from the group consisting of light, heat, an acid, and a base and generates a polar group, in a side chain, and has a fluorine atom or a silicon atom at a terminal rather than the cleavage group in a side chain is preferable.

Examples of such a repeating unit include the repeating units described in paragraphs [0037] and [0038] of WO2018/216812A.

Further, a repeating unit containing a cleavage group that generates a polar group due to an action of an acid is preferable as such a repeating unit, and suitable specific examples thereof include the following repeating units.

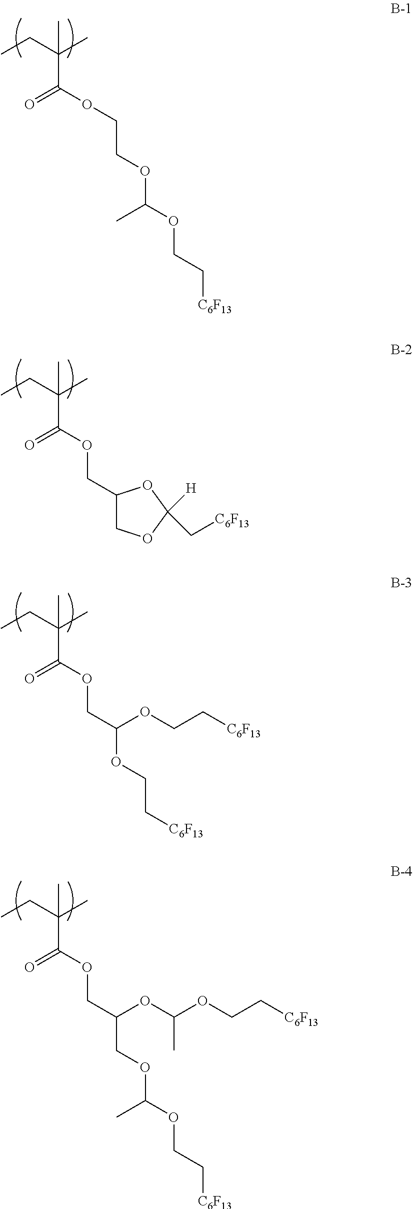

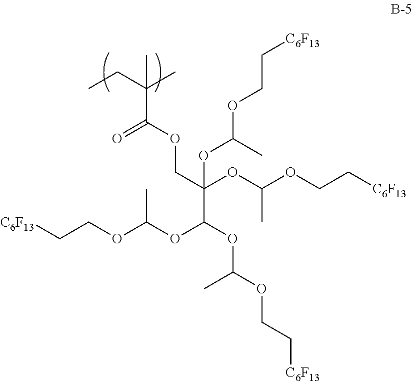

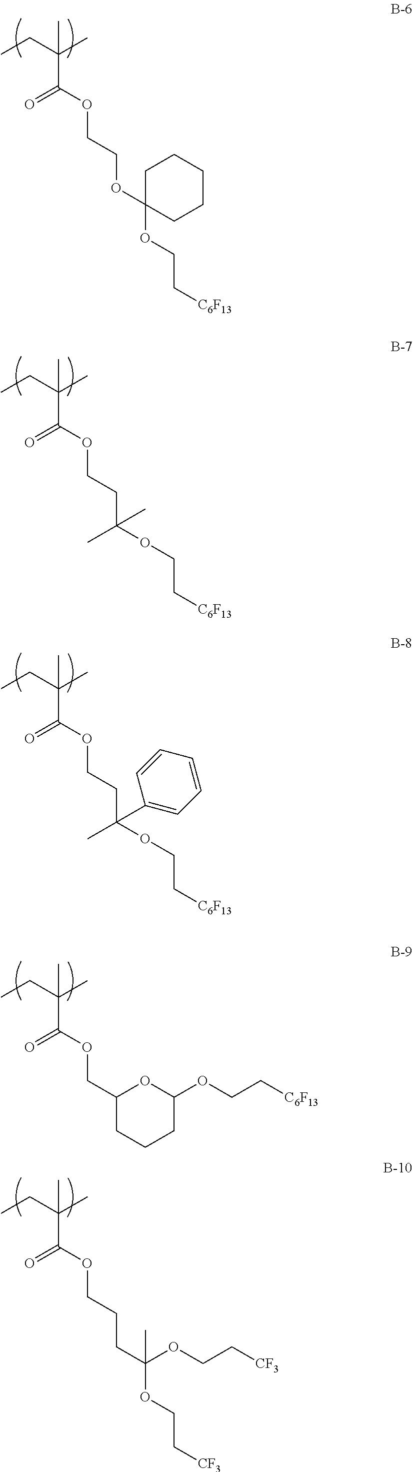

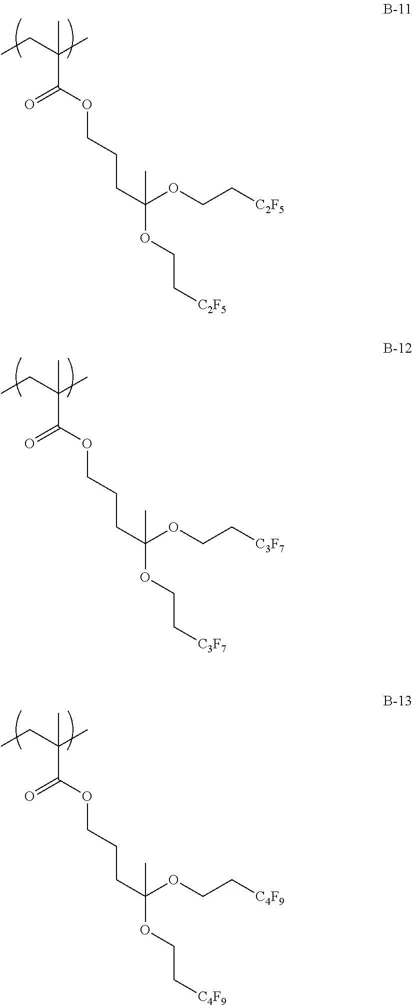

The content of the repeating unit containing a cleavage group in the photo-aligned polymer is not particularly limited, but is preferably 5% by mole or greater, more preferably 10% by mole or greater, still more preferably 15% by mole, and particularly preferably 20% by mole or greater and preferably 90% by mole or less, more preferably 70% by mole or less, still more preferably 50% by mole or less, particularly preferably 40% by mole or less, and most preferably 35% by mole or less with respect to all the repeating units of the photo-aligned polymer from the viewpoint of enhancing the aligning properties of the light absorption anisotropic layer described above.

The photo-aligned polymer may have other repeating units in addition to the repeating units described above.

Examples of the monomer forming other repeating units (radically polymerizable monomer) include an acrylic acid ester compound, a methacrylic acid ester compound, a maleimide compound, an acrylamide compound, acrylonitrile, a maleic acid anhydride, a styrene compound, and a vinyl compound.

A method of synthesizing the photo-aligned polymer is not particularly limited, and for example, the photo-aligned polymer can be synthesized by mixing a monomer forming the above-described repeating unit containing a photoreactive group, a monomer forming the above-described repeating unit containing a cleavage group, and a monomer forming any other repeating units and polymerizing the mixture in an organic solvent using a radically polymerization initiator.

The weight-average molecular weight (Mw) of the photo-aligned polymer is not particularly limited, but is preferably in a range of 10000 to 500000, more preferably in a range of 10000 to 300000, and still more preferably 30000 to 150000.

Here, the weight-average molecular weight in the present invention is a value measured by gel permeation chromatography (GPC) under the following conditions.
Solvent (eluent): tetrahydrofuran (THF)
Device name: TOSOH HLC-8320GPC
Column: Connect and use three of TOSOH TSKgel Super HZM-H (4.6 mm×15 cm)
Column temperature: 40° C.
Sample concentration: 0.1% by mass
Flow rate: 1.0 ml/min
Calibration curve: TSK standard polystyrene (manufactured by TOSOH Corporation), calibration curves of 7 samples with Mw of 2800000 to 1050 (Mw/Mn=1.03 to 1.06) are used.

<Photoacid Generator>

It is preferable that the composition for forming an optically anisotropic layer contains a photoacid generator.

The photoacid generator is not particularly limited, and a compound that is sensitive to actinic rays having a wavelength of 300 nm or greater and preferably a wavelength of 300 to 450 nm and generates an acid is preferable. Further, even a photoacid generator that is not directly sensitive to actinic rays having a wavelength of 300 nm or greater can be preferably used by being combined with a sensitizer as long as the photoacid generator is a compound that is sensitive to actinic rays having a wavelength of 300 nm or greater and generates an acid by being used in combination with a sensitizer.

As the photoacid generator, a photoacid generator that generates an acid having a pKa of 4 or less is preferable, a photoacid generator that generates an acid having a pKa of 3 or less is more preferable, and a photoacid generator that generates an acid having a pKa of 2 or less is still more preferable. In the present invention, the pKa basically denotes a pKa of an acid in water at 25° C. In a case where the pKa cannot be measured in water, the pKa denotes a pKa of an acid measured by changing water to a solvent suitable for the measurement. Specifically, the pKa described in Chemistry Handbook or the like can be referred to. As the acid having a pKa of 3 or less, sulfonic acid or phosphonic acid is preferable, and sulfonic acid is more preferable.

Examples of the photoacid generator include an onium salt compound, trichloromethyl-s-triazines, a sulfonium salt, an iodonium salt, quaternary ammonium salts, a diazomethane compound, an imide sulfonate compound, and an oxime sulfonate compound. Among these, an onium salt compound, an imide sulfonate compound, or an oxime sulfonate compound is preferable, and an onium salt compound or an oxime sulfonate compound is more preferable. The photoacid generator may be used alone or in combination of two or more kinds thereof

<Polymerization Initiator>

It is preferable that the composition for forming an optically anisotropic layer contains a polymerization initiator.

The polymerization initiator is not particularly limited, and examples thereof include a thermal polymerization initiator and a photopolymerization initiator depending on the type of the polymerization reaction.

A photopolymerization initiator capable of initiating the polymerization reaction by irradiation with ultraviolet rays is preferable as the polymerization initiator.

Examples of the photopolymerization initiator include α-carbonyl compounds (described in the specifications of U.S. Pat. Nos. 2,367,661A and 2,367,670A), acyloin ether (described in the specification of U.S. Pat. No. 2,448,828A), α-hydrocarbon-substituted aromatic acyloin compounds (described in the specification of U.S. Pat. No. 2,722,512A), polynuclear quinone compounds (described in the specifications of U.S. Pat. Nos. 3,046,127A and 2,951,758A), a combination of a triarylimidazole dimer and a p-aminophenyl ketone (described in the specification of U.S. Pat. No. 3,549,367A), acridine and phenazine compounds (described in the specifications of JP1985-105667A (JP-S60-105667A) and U.S. Pat. No. 4,239,850A), oxadiazole compounds (described in the specification of U.S. Pat. No. 4,212,970A), and acylphosphine oxide compounds (described in JP1988-040799B (JP-S63-040799B), JP1993-029234B (JP-H5-029234B), JP1998-095788A (JP-H10-095788A), and JP1998-029997A (JP-H10-029997A)).

<Solvent>

From the viewpoint of the workability, it is preferable that the composition for forming an optically anisotropic layer contains a solvent.

Specific examples of the solvent include ketones (such as acetone, 2-butanone, methyl isobutyl ketone, cyclohexanone, and cyclopentanone), ethers (such as dioxane and tetrahydrofuran), aliphatic hydrocarbons (such as hexane), alicyclic hydrocarbons (such as cyclohexane), aromatic hydrocarbons (such as toluene, xylene, and trimethylbenzene), carbon halides (such as dichloromethane, dichloroethane, dichlorobenzene, and chlorotoluene), esters (such as methyl acetate, ethyl acetate, and butyl acetate), water, alcohols (such as ethanol, isopropanol, butanol, and cyclohexanol), cellosolves (such as methylcellosolve and ethyl cellosolve), cellosolve acetates, sulfoxides (such as dimethylsulfoxide), and amides (such as dimethylformamide and dimethylacetamide).

These solvents may be used alone or in combination of two or more kinds thereof.

It is preferable that the optically anisotropic layer of the laminate according to the embodiment of the present invention is a layer that is formed of the above-described composition for forming an optically anisotropic layer and has a surface having an alignment control ability. More specifically, it is preferable that the optically anisotropic layer is a layer formed by generating an acid from a photoacid generator in a coating film of the composition for forming an optically anisotropic layer and performing a photo-alignment treatment.

That is, it is preferable that the optically anisotropic layer is formed by a method of performing a curing treatment on a coating film formed of the above-described composition for forming an optically anisotropic layer, performing a treatment of generating an acid from a photoacid generator in the coating film (hereinafter, also simply referred to as “acid generation treatment”), and performing a photo-alignment treatment.

Further, as described below, the curing treatment and the acid generation treatment may be performed at the same time.

Hereinafter, a method of performing the curing treatment will be described in detail.

A method of forming a coating film formed of the composition for forming an optically anisotropic layer is not particularly limited, and examples thereof include a method of coating a support with the composition for forming an optically anisotropic layer and performing a drying treatment on the support as necessary.

Examples of the support include a glass substrate and a polymer film.

Examples of the material of the polymer film include a cellulose-based polymer, an acrylic polymer containing an acrylic acid ester polymer such as polymethyl methacrylate or a lactone ring-containing polymer, a thermoplastic norbornene-based polymer, a polycarbonate-based polymer, a polyester-based polymer such as polyethylene terephthalate or polyethylene naphthalate, a styrene-based polymer such as polystyrene or an acrylonitrile-styrene copolymer, a polyolefin-based polymer such as polyethylene, polypropylene, or an ethylene-propylene copolymer, a vinyl chloride-based polymer, an amide-based polymer such as nylon or aromatic polyamide, an imide-based polymer, a sulfone-based polymer, a polyether sulfone-based polymer, a polyether ether ketone-based polymer, a polyphenylene sulfide-based polymer, a vinylidene chloride-based polymer, a vinyl alcohol-based polymer, a vinyl butyral-based polymer, an arylate-based polymer, a polyoxymethylene-based polymer, an epoxy-based polymer, and a polymer obtained by mixing such polymers.

Further, an alignment layer may be disposed on the support. In this case, a known alignment layer such as a rubbing alignment layer or a photo-alignment layer may be used as the alignment layer, but a photo-alignment layer is preferably used from the viewpoint of suppressing alignment defects starting from shavings generated by rubbing. From the viewpoint of suppressing reticulation of the laminate, it is preferable that the laminate does not have an alignment layer at a time at which the laminate according to the embodiment of the present invention is formed. Therefore, it is preferable that the alignment layer and the support are peelable.

The thickness of the support is not particularly limited, but is preferably in a range of 5 to 200 μm, more preferably in a range of 10 to 100 μm, and still more preferably in a range of 20 to 90 μm.

A method of coating the support with the composition for forming an optically anisotropic layer is not particularly limited, and examples of the coating method include a spin coating method, an air knife coating method, a curtain coating method, a roller coating method, a wire bar coating method, a gravure coating method, and a die coating method.

Next, a curing treatment and an acid generation treatment are performed on the coating film formed of the composition for forming an optically anisotropic layer.

Examples of the curing treatment include a light irradiation treatment and a heat treatment.

Further, the conditions of the curing treatment are not particularly limited, but it is preferable that ultraviolet rays are used in the polymerization by irradiation with light. The irradiation amount is preferably in a range of 10 mJ/cm² to 50 J/cm², more preferably in a range of 20 mJ/cm² to 5 J/cm², still more preferably in a range of 30 mJ/cm² to 3 J/cm², and particularly preferably in a range of 50 to 1000 mJ/cm². Further, the curing treatment may be performed under heating conditions in order to promote the polymerization reaction.

The treatment of generating an acid from the photoacid generator in the coating film is a treatment of irradiating the coating film with light to which the photoacid generator contained in the composition for forming an optically anisotropic layer is sensitive to generate an acid. The cleavage in the cleavage group proceeds and the group having a fluorine atom or a silicon atom is eliminated by performing the present treatment.

The light irradiation treatment performed in the above-described treatment may be a treatment in which the photoacid generator is sensitive to light, and examples thereof include a method of irradiating the coating film with ultraviolet rays. As a light source, a lamp that emits ultraviolet rays, such as a high-pressure mercury lamp or a metal halide lamp, can be used. Further, the irradiation amount is preferably in a range of 10 mJ/cm² to 50 J/cm², more preferably in a range of 20 mJ/cm² to 5 J/cm², still more preferably in a range of 30 mJ/cm² to 3 J/cm², and particularly preferably in a range of 50 to 1000 mJ/cm².

The curing treatment and the acid generation treatment may be performed sequentially or simultaneously. Particularly, in a case where the photoacid generator and the polymerization initiator in the composition for forming an optically anisotropic layer are sensitive to light having the same wavelength, it is preferable that the curing treatment and the acid generation treatment are performed simultaneously from the viewpoint of productivity.

A method for the photo-alignment treatment to be performed on the coating film (including a cured film formed of the composition for forming an optically anisotropic layer which has been subjected to a curing treatment) formed of the composition for forming an optically anisotropic layer which has been formed in the above-described manner is not particularly limited, and examples thereof include known methods.

The photo-alignment treatment may be performed by, for example, a method of irradiating the coating film (including a cured film formed of the composition for forming an optically anisotropic layer which has been subjected to a curing treatment) formed of the composition for forming an optically anisotropic layer with polarized light or irradiating the surface of the coating film with non-polarized light in an oblique direction.

In the photo-alignment treatment, the polarized light to be applied is not particularly limited, and examples thereof include linearly polarized light, circularly polarized light, and elliptically polarized light. Among these, and linearly polarized light is preferable.

Further, “oblique direction” in which non-polarized light is applied is not particularly limited as long as the direction is inclined at a polar angle θ (0<θ<90°) with respect to the normal direction of the surface of the coating film, and the polar angle θ can be appropriately selected depending on the purpose thereof, but is preferably in a range of 20° to 80°.

The wavelength of the polarized light or the non-polarized light is not particularly limited as long as the photo-aligned group is sensitive to light, and examples thereof include ultraviolet rays, near-ultraviolet rays, and visible light. Among these, near-ultraviolet rays having a wavelength of 250 to 450 nm are preferable.

Further, examples of a light source for applying polarized light or non-polarized light include a xenon lamp, a high-pressure mercury lamp, an ultra-high pressure mercury lamp, and a metal halide lamp. The wavelength range of irradiation can be limited by using an interference filter, a color filter, or the like for ultraviolet rays or visible rays obtained from such a light source. Further, linearly polarized light can be obtained by using a polarizing filter or a polarizing prism for light from such a light source.

The integrated light amount of polarized or non-polarized light is not particularly limited, but is preferably in a range of 1 to 300 mJ/cm² and more preferably in a range of 5 to 100 mJ/cm².

The illuminance of polarized light or non-polarized light is not particularly limited, but is preferably in a range of 0.1 to 300 mW/cm² and more preferably in a range of 1 to 100 mW/cm².

In the description above, the aspect in which the curing treatment and the acid generation treatment are performed before the photo-alignment treatment has been described, but the present invention is not limited thereto, and the curing treatment and acid generation treatment may be performed simultaneously during the photo-alignment treatment.

The thickness of the optically anisotropic layer is not particularly limited, but is preferably in a range of 0.1 to 10 μm and more preferably in a range of 0.5 to 5 μm.

The optically anisotropic layer of the laminate according to the embodiment of the present invention may include a first optically anisotropic layer and a second optically anisotropic layer, and suitable examples thereof include an aspect in which the above-described light absorption anisotropic layer, the first optically anisotropic layer, and the second optically anisotropic layer are directly laminated in this order, that is, an aspect in which the laminate includes the optically anisotropic layer described before the present paragraph as the first optically anisotropic layer and another optically anisotropic layer as the second optically anisotropic layer.

Here, it is preferable that the second optically anisotropic layer is formed of a liquid crystal composition containing a liquid crystal compound.

Further, examples of the liquid crystal composition for forming the second optically anisotropic layer include a composition obtained by blending a liquid crystal compound, a polymerization initiator, a solvent, and the like, described in the section of the composition for forming an optically anisotropic layer above.

Further, the thickness of the second optically anisotropic layer is not particularly limited, but is preferably in a range of 0.1 to 10 μm, more preferably in a range of 0.2 to 5 μm, and still more preferably in a range of 0.3 to 2 μm.

From the viewpoint of the usefulness as a compensation layer of a circularly polarizing plate or a liquid crystal display device, it is preferable that the first optically anisotropic layer of the laminate according to the embodiment of the present invention is a positive A-plate.

Further, from the viewpoint of optical compensation of the first optically anisotropic layer in an oblique direction, it is preferable that the second optically anisotropic layer of the optical laminate according to the embodiment of the present invention is a positive C-plate and also preferable that the second optically anisotropic layer is a twisted alignment layer.

Further, it is also preferable that the laminate includes a positive C-plate or a twisted alignment layer as a third optically anisotropic layer.

Here, the positive A-plate and the positive C-plate are defined as follows.

In a case where the in-plane refractive index of the film in a slow axis direction (a direction in which the in-plane refractive index is maximized) is defined as nx, the in-plane refractive index of the film in a direction orthogonal to an in-plane slow axis is defined as ny, and the refractive index of the film in the thickness direction is defined as nz, the positive A-plate satisfies the relationship of Expression (A1), and the positive C-plate satisfies the relationship of Expression (C1). Further, Rth of the positive A-plate represents a positive value, and Rth of the positive C-plate represents a negative value.

nx>ny≈nz Expression (A1)

nz>nx≈ny Expression (C1)

The symbol “≈” includes not only a case where both are completely the same as each other but also a case where both are substantially the same as each other.

Here, “substantially the same as each other” denotes that in the positive A-plate, for example, “ny≈nz” includes even a case where (ny−nz)×d (where d represents the thickness of the film) is in a range of −10 to 10 nm and preferably in a range of −5 to 5 nm, and “nx≈nz” includes even a case where (nx−nz)×d is in a range of −10 to 10 nm and preferably in a range of −5 to 5 nm. Further, in the positive C-plate, for example, “nx≈ny” includes even a case where (nx−ny)×d (where d represents the thickness of the film) is in a range of 0 to 10 nm and preferably in a range of 0 to 5 nm.

In a case where the optically anisotropic layer (the first optically anisotropic layer in a case where the laminate has both the first optically anisotropic layer and the second optically anisotropic layer, the same applies hereinafter) of the laminate according to the embodiment of the present invention is a positive A-plate, from the viewpoint of functioning as a λ/4 plate, Re (550) is preferably in a range of 100 to 180 nm, more preferably in a range of 120 to 160 nm, and still more preferably in a range of 130 to 150 nm.

Here, “λ/4 plate” is a plate having a λ/4 function, specifically, a plate having a function of converting linearly polarized light having a specific wavelength into circularly polarized light (or converting circularly polarized light into linearly polarized light).

In the laminate according to the embodiment of the present invention, since the light absorption anisotropic layer has a high refractive index of the dye, internal reflection at an interface particularly on the viewing side may be a problem. In this case, it is preferable to provide a cured layer consisting of a liquid crystal or to provide pigment concentration distribution for adjusting the refractive index.

Further, from the viewpoint of improving the light durability of the organic dichroic coloring agent contained in the light absorption anisotropic layer, it is also preferable that the laminate according to the embodiment of the present invention is provided with an oxygen blocking layer.

Further, the laminate according to the embodiment of the present invention can be provided with a resin film such as tack or PET, a hard coat layer, glass, an antireflection layer, an antiglare layer, an antifouling layer, or the like as a surface protective film for the purpose of preventing damage due to contact, imparting glassiness, improving visibility by suppressing surface reflection, preventing stains, and the like.

[Polarizing Plate]

A polarizing plate according to the embodiment of the present invention includes the above-described laminate according to the embodiment of the present invention.

In addition, the polarizing plate according to the embodiment of the present invention can be used as a circularly polarizing plate in a case where the optically anisotropic layer of the above-described laminate according to the embodiment of the present invention is a λ/4 plate.

In a case where the polarizing plate according to the embodiment of the present invention is used as a circularly polarizing plate, the angle between the slow axis of the optically anisotropic layer (λ/4 plate) of the above-described laminate according to the embodiment of the present invention and the absorption axis of the light absorption anisotropic layer of the above-described laminate according to the embodiment of the present invention is preferably in a range of 30° to 60°, more preferably in a range of 40° to 50°, still more preferably in a range of 42° to 48°, and particularly preferably 45°.

[Image Display Device]

An image display device according to the embodiment of the present invention is an image display device including the optical laminate according to the embodiment of the present invention or the polarizing plate according to the embodiment of the present invention.

A display element used in the image display device according to the embodiment of the present invention is not particularly limited, and examples thereof include a liquid crystal cell, an organic EL display panel, and a plasma display panel.

Among these, a liquid crystal cell or an organic EL display panel is preferable, and a liquid crystal cell is more preferable. That is, in the image display device according to the embodiment of the present invention, a liquid crystal display device formed of a liquid crystal cell as a display element or an organic EL display device formed of an organic EL display panel as a display element is preferable.

It is preferable that the liquid crystal cell used for the liquid crystal display device is in a vertical alignment (VA) mode, an optically compensated bend (OCB) mode, an in-plane-switching (IPS) mode, a fringe-field-switching (FFS) mode, or a twisted nematic (TN) mode, but the present invention is not limited thereto.

As the organic EL display device, an aspect of a display device including a polarizer, the optical laminate according to the embodiment of the present invention, and an organic EL display panel in order from the viewing side is suitably exemplified.

The organic EL display panel is a member that forms a light emitting layer or a plurality of organic compound thin films including a light emitting layer between a pair of electrodes of an anode and a cathode, and a hole injection layer, a hole transport layer, an electron injection layer, an electron transport layer, a protective layer, and the like may also be provided in addition to the light emitting layer, and each of these layers may have other functions. Various materials can be used for forming each layer.

[Applications]

The laminate according to the embodiment of the present invention can be used for various articles having a curved surface. For example, the laminate can be used for a rollable display having a curved surface, an in-vehicle display, a lens of sunglasses, a lens of goggles for an image display device, and the like. Since the laminate in the present embodiment can be bonded onto a curved surface or integrally molded with a resin, the laminate contributes to improvement in designability.

It is also preferable that the laminate is used for an in-vehicle display optical system such as a head-up display, an optical system such as augmented reality (AR) eyeglasses or virtual reality (VR) eyeglasses, or an optical sensor such as light detection and ranging (LiDAR), a face recognition system, or polarization imaging.

### EXAMPLES

Hereinafter, the present invention will be described in more detail with reference to examples. Materials, used amounts, ratios, treatment contents, treatment procedures, and the like described in the following examples can be appropriately changed without departing from the spirit of the present invention. Therefore, the scope of the present invention should not be limitatively interpreted by the following examples.

[Synthesis of Photo-Aligned Polymer PA-1]

The following photo-aligned polymer PA-1 was synthesized with reference to Example 24 of WO2019/225632A.

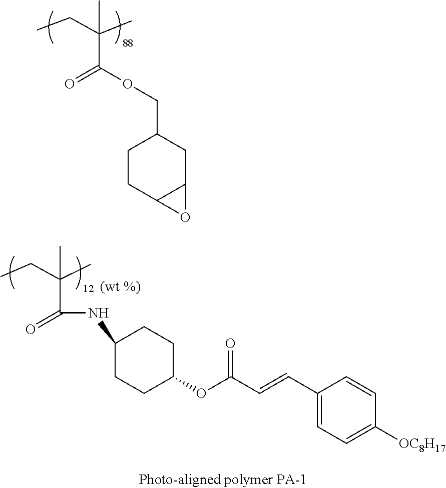

[Synthesis of Cleavage Group-Containing Photo-Aligned Polymer FP-1]

As shown in the scheme described below, a 200 mL three-neck flask provided with a stirrer, a thermometer, and a reflux condenser was charged with 2-hydroxyethyl methacrylate (13.014 g, 100 mmol), toluene (100 g), and dibutylhydroxytoluene (BHT) (10.0 mg), and the mixture was stirred at room temperature (23° C.). Next, 10-camphorsulfonic acid (230.3 mg, 0.1 mmol) was added to the obtained solution, and the solution was stirred at room temperature. Next, 2-(perfluorohexyl)ethyl vinyl ether (39.014 g, 100 mmol) was added dropwise to the obtained solution over 1.5 hours, and the solution was further stirred at room temperature for 3 hours. Ethyl acetate (200 mL) and sodium bicarbonate water (200 mL) were added to the obtained solution for liquid separation purification, and the organic phase was taken out. Magnesium sulfate was added to the obtained organic phase, the mixture was dried and filtered, and a solvent was distilled off from the obtained filtrate, thereby obtaining 46.8 g of a monomer mB-1 represented by Formula mB-1.

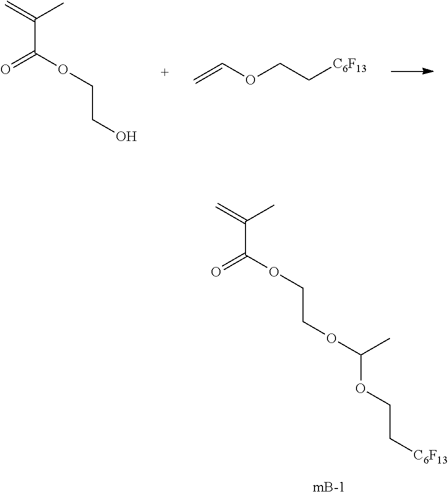

The following monomers mA-125 and mC-1 were synthesized or prepared with reference to WO2019/225632A.

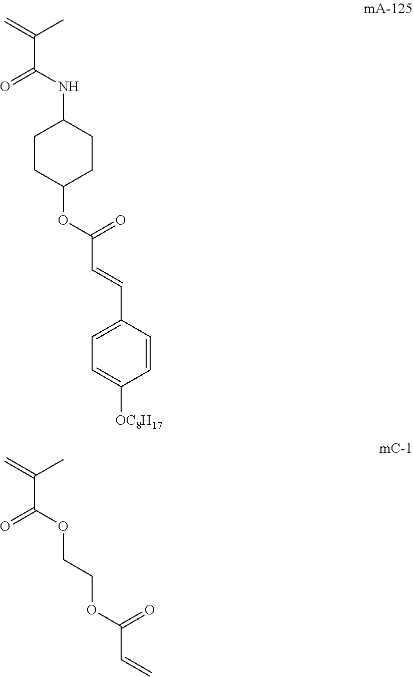

A flask provided with a cooling pipe, a thermometer, and a stirrer was charged with 5.5 parts by mass of the monomer mA-125 and 10 parts by mass of 2-butanone as a solvent, and the mixture was refluxed by being heated in a water bath while nitrogen was allowed to flow in the flask at 5 mL/min. Here, a solution obtained by mixing 3.0 parts by mass of the monomer mB-1, 1.5 parts by mass of the monomer mC-1, 0.062 parts by mass of 2,2′-azobis(isobutyronitrile) as a polymerization initiator, and 13 parts by mass of 2-butanone as a solvent was added dropwise to the flask over 3 hours, and the solution was further stirred for 3 hours while the reflux state was maintained. After completion of the reaction, the solution was allowed to be naturally cooled to room temperature, and 10 parts by mass of 2-butanone was added to the solution for dilution, thereby obtaining an approximately 20% by mass polymer solution. The obtained polymer solution was put into an excessive amount of methanol to precipitate a polymer, and the recovered precipitate was filtered by separation, washed with a large amount of methanol, and blast-dried at 50° C. for 12 hours, thereby obtaining the following cleavage group-containing photo-aligned polymer FP-1.

Cleavage group-containing photo-aligned polymer FP-1 (numerical values in the following formulae represent the content in units of % by mole)

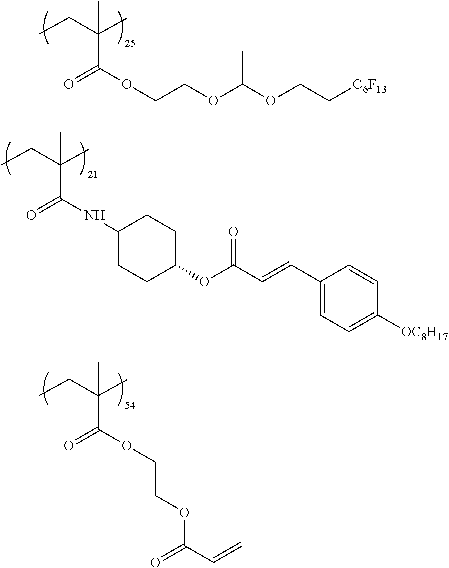

### Example 1

<Preparation of Cellulose Acylate Film 1>

(Preparation of Core Layer Cellulose Acylate Dope)

The following composition was put into a mixing tank and stirred to dissolve each component, thereby preparing a cellulose acetate solution used as a core layer cellulose acylate dope.

Core Layer Cellulose Acylate Dope
Cellulose acetate having acetyl substitution degree of 2.88: 100 parts by mass
Polyester compound B described in example of JP2015-227955A: 12 parts by mass
Compound F shown below: 2 parts by mass
Methylene chloride (first solvent): 430 parts by mass
Methanol (second solvent): 64 parts by mass

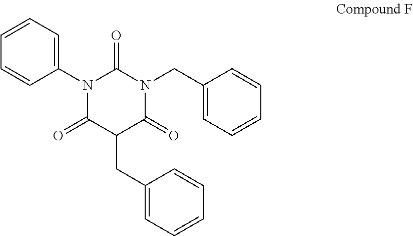 [SMILES: O=C1C(Cc2ccccc2)C(=O)N(c2ccccc2)C(=O)N1Cc1ccccc1]

(Preparation of Outer Layer Cellulose Acylate Dope)

10 parts by mass of the following matting agent solution was added to 90 parts by mass of the above-described core layer cellulose acylate dope, thereby preparing a cellulose acetate solution used as an outer layer cellulose acylate dope.

Matting Agent Solution
Silica particles with average particle size of 20 nm (AEROSIL R972, manufactured by Nippon Aerosil Co., Ltd.): 2 parts by mass
Methylene chloride (first solvent): 76 parts by mass
Methanol (second solvent): 11 parts by mass
Core layer cellulose acylate dope described above: 1 parts by mass

(Preparation of Cellulose Acylate Film 1)

The core layer cellulose acylate dope and the outer layer cellulose acylate dope were filtered through filter paper having an average pore size of 34 μm and a sintered metal filter having an average pore size of 10 μm, and three layers which were the core layer cellulose acylate dope and the outer layer cellulose acylate dopes provided on both sides of the core layer cellulose acylate dope were simultaneously cast from a casting port onto a drum at 20° C. (band casting machine).

Next, the film was peeled off in a state where the solvent content was approximately 20% by mass, both ends of the film in the width direction were fixed by tenter clips, and the film was dried while being stretched at a stretching ratio of 1.1 times in the lateral direction.

Thereafter, the film was further dried by being transported between the rolls of the heat treatment device to prepare an optical film having a thickness of 40 μm, and the optical film was used as a cellulose acylate film 1. The in-plane retardation of the obtained cellulose acylate film 1 was 0 nm.

<Formation of Photo-Alignment Layer PA1>

The cellulose acylate film 1 was continuously coated with a coating solution PA1 for forming an alignment layer described below with a wire bar. The support on which the coating film was formed was dried with hot air at 140° C. for 120 seconds, and the coating film was irradiated with polarized ultraviolet rays (10 mJ/cm², using an ultra-high pressure mercury lamp) in a 45° direction with respect to the longitudinal direction on the coating film to form a photo-alignment layer PA1, thereby obtaining a TAC film provided with a photo-alignment layer.

The film thickness of the photo-alignment layer PA1 was 0.5 μm.

(Coating Solution PA1 for Forming Alignment Layer)
Photo-aligned polymer PA-1 shown above: 100.00 parts by mass
Thermal acid generator TAG-1 shown below: 3.00 parts by mass
Diisopropylethylamine: 0.60 parts by mass
Butyl acetate: 953.12 parts by mass
Methyl ethyl ketone: 238.28 parts by mass

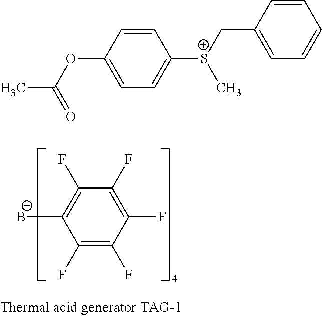

<Formation of First Optically Anisotropic Layer>

The following polymerizable liquid crystal compound A (65 parts by mass) exhibiting reverse wavelength dispersibility, the following polymerizable liquid crystal compound B (35 parts by mass) exhibiting reverse wavelength dispersibility, a photopolymerization initiator (IRGACURE 907, manufactured by BASF SE) (3 parts by mass), a sensitizer (KAYACURE DETX, manufactured by Nippon Kayaku Co., Ltd.) (1 part by mass), the following horizontal alignment agent (0.3 parts by mass), the following photoacid generator (B-1-1) (3.0 parts by mass), and the above-described cleavage group-containing photo-aligned polymer FP-1 (2 parts by mass) were dissolved in cyclopentanone (193 parts by mass), thereby preparing a solution for forming an optically anisotropic layer.

The photo-alignment layer PA-1 was coated with the above-described solution for forming an optically anisotropic layer using a #7 wire bar coater, heated at 60° C. for 2 minutes, and irradiated with ultraviolet rays at an irradiation amount of 100 mJ/cm² using a UV-LED (wavelength of 365 nm) while the state of the layer was maintained at 60° and nitrogen was purged to have an atmosphere with an oxygen concentration of 1.0% by volume or less. Further, the layer was heated at 130° C. for 1 minute and irradiated with polarized ultraviolet rays polarized in the longitudinal direction (10 mJ/cm², using an ultra-high pressure mercury lamp), thereby forming a first optically anisotropic layer 1 having a photo-alignment function. The film thickness of the first optically anisotropic layer 1 was 2.5 μm.

Further, it was confirmed that the formed first optically anisotropic layer was a positive A-plate satisfying Expression (I) and a photo-aligned group derived from the cleavage group-containing photo-aligned polymer FP-1 was unevenly distributed on a side opposite to the photo-alignment layer PA-1 (air interface side).

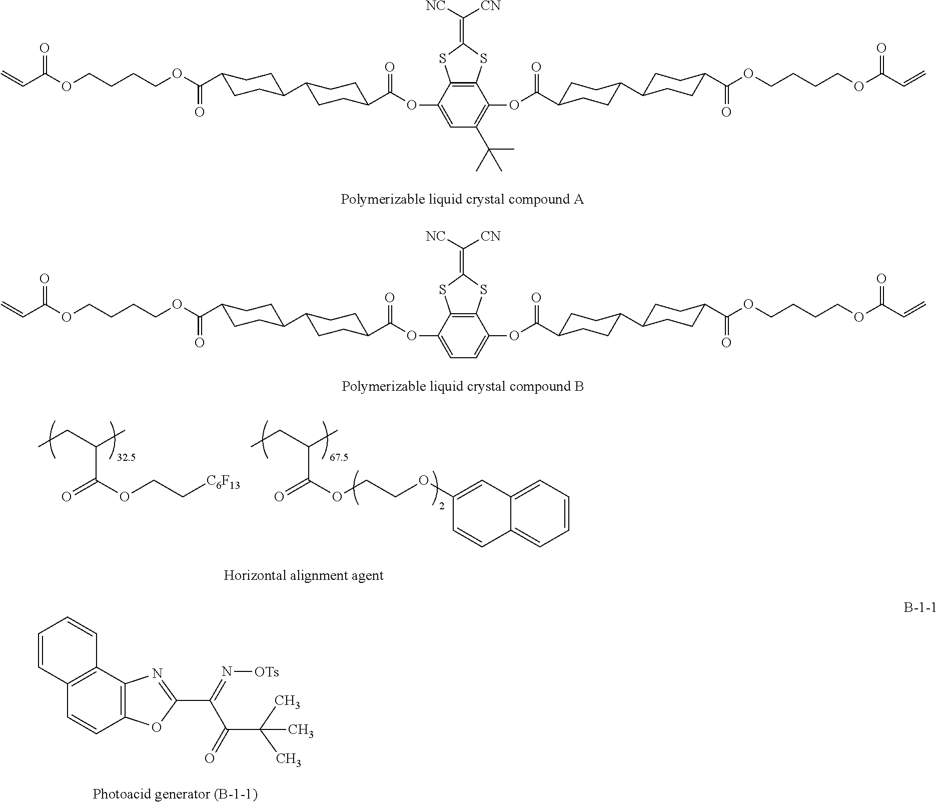

<Formation of Light Absorption Anisotropic Layer P1>

The obtained first optically anisotropic layer was continuously coated with the following composition P1 for forming a light absorption anisotropic layer using a wire bar to form a coating layer P1.

Next, the coating layer P1 was heated at 140° C. for 30 seconds, and the coating layer P1 was cooled to room temperature (23° C.).

Next, the coating layer was heated at 90° C. for 60 seconds and cooled to room temperature again.

Thereafter, the coating layer was irradiated with an LED lamp (center wavelength of 365 nm) for 2 seconds under an irradiation condition of an illuminance of 200 mW/cm², thereby preparing a light absorption anisotropic layer P1 on the first optically anisotropic layer 1.

The film thickness of the light absorption anisotropic layer P1 was 0.4 μm.

Composition of Composition P1 for Forming Light Absorption Anisotropic Layer
Dichroic substance D-1 shown below: 0.36 parts by mass
Dichroic substance D-2 shown below: 0.53 parts by mass
Dichroic substance D-3 shown below: 0.31 parts by mass
Polymer liquid crystal compound P-1 shown below: 3.58 parts by mass
Polymerization initiator IRGACURE OXE-02 (manufactured by BASF SE): 0.050 parts by mass
Interface improver F-1 shown below: 0.026 parts by mass
Interface improver F-2 shown below: 0.026 parts by mass
Cyclopentanone: 45.00 parts by mass
Tetrahydrofuran: 45.00 parts by mass
Benzyl alcohol: 5.00 parts by mass

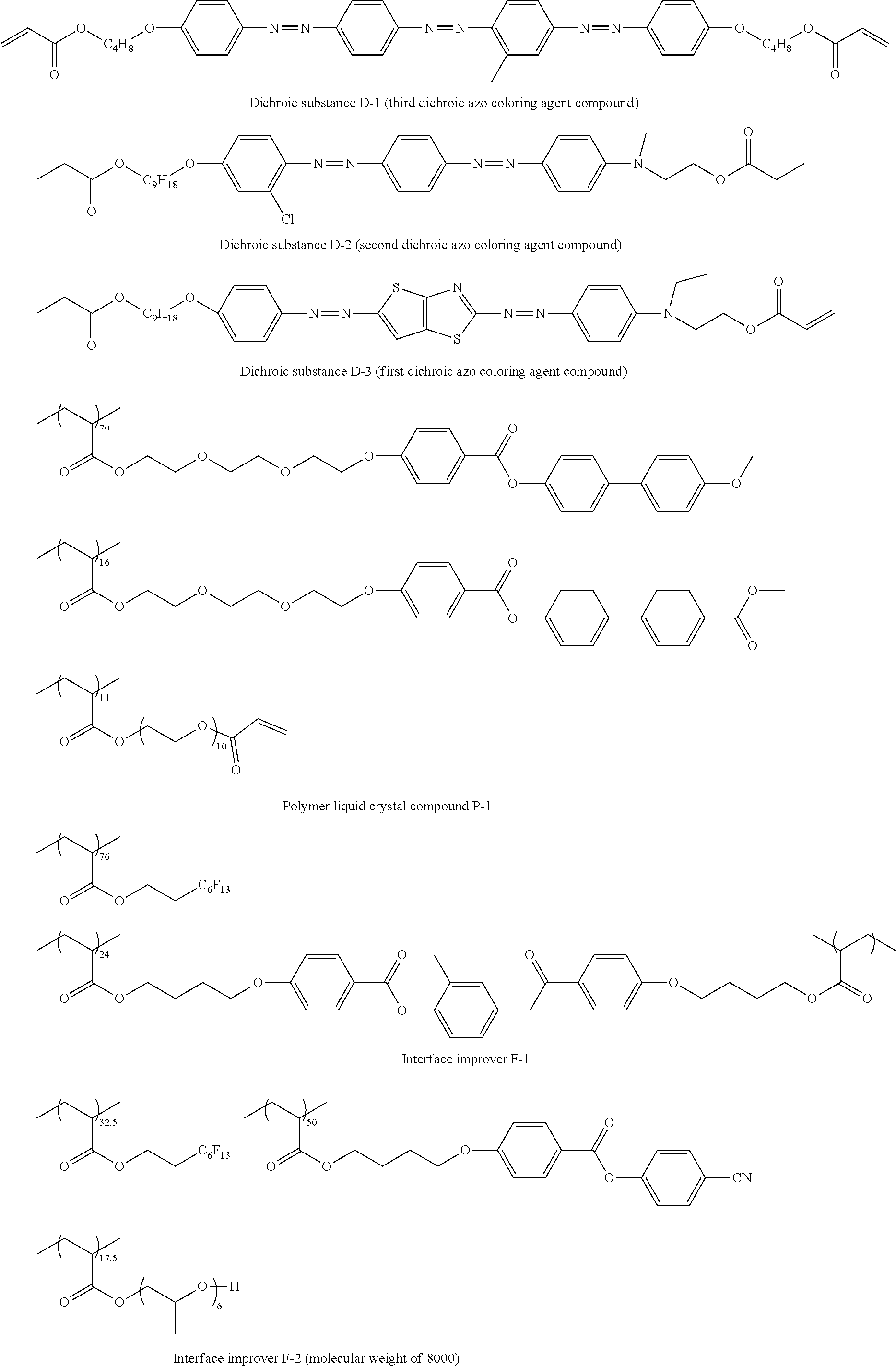

<Formation of Cured Layer N1>

The formed light absorption anisotropic layer P1 was continuously coated with the following composition N1 for forming a cured layer using a wire bar, thereby forming a cured layer N1.

Thereafter, the cured layer N1 was dried at room temperature and irradiated using a high-pressure mercury lamp under an irradiation condition of an illuminance of 28 mW/cm² for 15 seconds, thereby preparing a cured layer N1 on the light absorption anisotropic layer P1.

The film thickness of the cured layer N1 was 0.05 μm (50 nm).

Composition of Composition N1 for Forming a Cured Layer
Mixture L1 of rod-like liquid crystal compounds shown below: 2.61 parts by mass
Modified trimethylolpropane triacrylate shown below: 0.11 parts by mass
Photopolymerization initiator I-1 shown below: 0.05 parts by mass
Interface improver F-3 shown below: 0.21 parts by mass
Methyl isobutyl ketone: 297 parts by mass

Mixture L1 of rod-like liquid crystal compounds (the numerical values in the following formulae represent the content in units of % by mass, and R represents a group bonded via an oxygen atom).

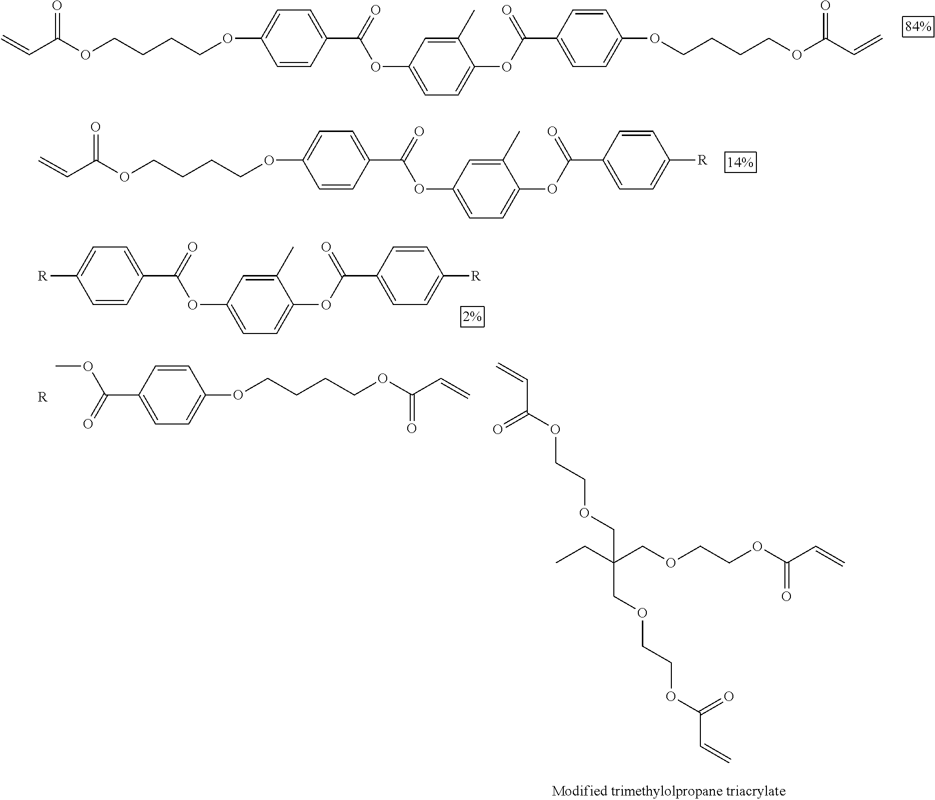

Photopolymerization initiator I-1 shown below

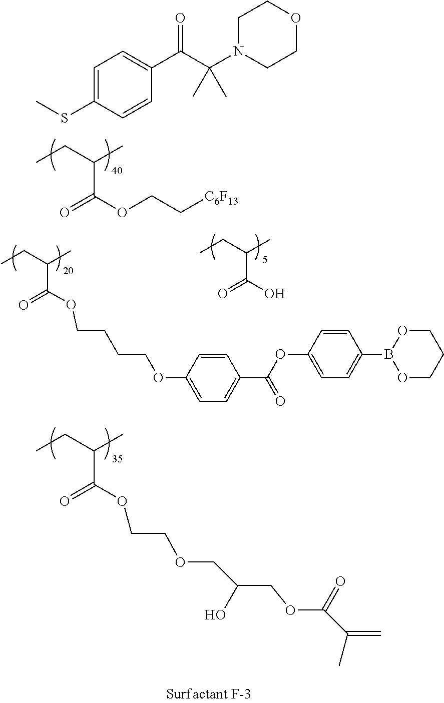

<Formation of Oxygen Blocking Layer B1>

The cured layer N1 was continuously coated with a coating solution having the following composition using a wire bar. Thereafter, the cured layer was dried with hot air at 100° C. for 2 minutes, thereby preparing a laminated film 1B in which a polyvinyl alcohol (PVA) layer having a thickness of 1.0 μm was formed on the cured layer N1 as an oxygen blocking layer B1.

Composition of Composition B1 for Forming Oxygen Blocking Layer
Modified polyvinyl alcohol shown below: 3.80 parts by mass
Initiator Irg2959: 0.20 parts by mass
Water: 70 parts by mass
Methanol: 30 parts by mass

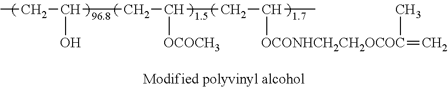

<Preparation of Surface Protective Layer H1>

As described below, a coating solution for forming each layer was prepared to form each layer, thereby preparing a surface protective layer H1.

(Preparation of Composition for Forming Hard Coat Layer)

Trimethylolpropane triacrylate (VISCOAT #295 (manufactured by Osaka Organic Chemical Industry, Ltd.)) (750.0 parts by mass), poly(glycidyl methacrylate) having a mass average molecular weight of 15000 (270.0 parts by mass), methyl ethyl ketone (730.0 parts by mass), cyclohexanone (500.0 parts by mass), and a photopolymerization initiator (IRGACURE 184, manufactured by BASF SE) (50.0 parts by mass) were mixed. The obtained mixture was filtered through a polypropylene filter having a pore diameter of 0.4 thereby preparing a composition for forming a hard coat layer.

(Preparation of Composition a for Forming Medium Refractive Index Layer)

A ZrO₂ fine particle-containing hard coating agent (DeSolite Z7404 [refractive index: 1.72, concentration of solid contents: 60% by mass, content of zirconium oxide fine particles: 70% by mass (with respect to solid content), average particle diameter of zirconium oxide fine particles: approximately 20 nm, composition of solvent: methyl isobutyl ketone/methyl ethyl ketone=9/1, manufactured by JSR Corporation]) (5.1 parts by mass), a mixture of dipentaerythritol pentaacrylate and dipentaerythritol hexaacrylate (DPHA) (1.5 parts by mass), a photopolymerization initiator (IRGACURE 907, manufactured by Ciba Specialty Chemicals) (0.05 parts by mass), methyl ethyl ketone (66.6 parts by mass), methyl isobutyl ketone (7.7 parts by mass), and cyclohexanone (19.1 parts by mass) were mixed. The obtained mixture was sufficiently stirred and filtered through a polypropylene filter having a pore size of 0.4 thereby preparing a composition A for forming a medium refractive index layer.

(Preparation of Composition B for Forming Medium Refractive Index Layer)

A mixture of dipentaerythritol pentaacrylate and dipentaerythritol hexaacrylate (DPHA) (4.5 parts by mass), a photopolymerization initiator (IRGACURE 184, manufactured by Ciba Specialty Chemicals) (0.14 parts by mass), methyl ethyl ketone (66.5 parts by mass), methyl isobutyl ketone (9.5 parts by mass), and cyclohexanone (19.0 parts by mass) were mixed. The obtained mixture was sufficiently stirred and filtered through a polypropylene filter having a pore size of 0.4 thereby preparing a composition B for forming a medium refractive index layer.

An appropriate amount of the composition A for forming a medium refractive index layer and an appropriate amount of the composition B for forming a medium refractive index layer were mixed such that the refractive index reached 1.62 to prepare a composition for forming a medium refractive index layer.

(Preparation of Composition for Forming High Refractive Index Layer)

A ZrO₂ fine particle-containing hard coating agent (DeSolite Z7404 [refractive index: 1.72, concentration of solid contents: 60% by mass, content of zirconium oxide fine particles: 70% by mass (with respect to solid content), average particle diameter of zirconium oxide fine particles: approximately 20 nm, composition of solvent: methyl isobutyl ketone/methyl ethyl ketone=9/1, manufactured by JSR Corporation]) (15.7 parts by mass), methyl ethyl ketone (61.9 parts by mass), methyl isobutyl ketone (3.4 parts by mass), and cyclohexanone (1.1 parts by mass) were mixed. The obtained mixture was filtered through a polypropylene filter having a pore size of 0.4 thereby preparing a composition for forming a high refractive index layer.

(Preparation of Composition for Forming Low Refractive Index Layer)

(Synthesis of Perfluoroolefin Copolymer (1))

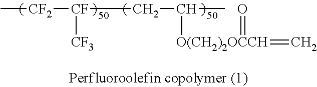

In the structural formula, 50:50 represents the molar ratio.

An autoclave provided with a stainless steel stirrer having an internal volume of 100 ml was charged with ethyl acetate (40 ml), hydroxyethyl vinyl ether (14.7 g), and dilauroyl peroxide (0.55 g), and the inside of the system was degassed and substituted with nitrogen gas. Further, hexafluoropropylene (25 g) was introduced into the autoclave and the mixture was heated to 65° C. The pressure at a time at which the temperature in the autoclave reached 65° C. was 0.53 MPa (5.4 kg/cm²). The temperature was maintained, the reaction was allowed to continue for 8 hours, and the heating was stopped at a time at which the pressure reached 0.31 MPa (3.2 kg/cm²), and the mixture was naturally cooled. The unreacted monomer was separated out at a time at which the internal temperature was lowered to room temperature, and the autoclave was opened to take out the reaction solution. The obtained reaction solution was poured into an excessive amount of hexane, the solvent was removed by decantation, and the precipitated polymer was taken out. Further, the obtained polymer was dissolved in a small amount of ethyl acetate, reprecipitated twice from hexane to completely remove the residual monomer, and dried, thereby obtaining a polymer (28 g).

Next, the polymer (20 g) was dissolved in N,N-dimethylacetamide (100 ml) to obtain a solution, acrylic acid chloride (11.4 g) was added dropwise to the solution under ice-cooling, and the solution was stirred at room temperature for 10 hours. Ethyl acetate was added to the reaction mixture, the reaction solution was washed with water, the organic phase was extracted and concentrated, and the obtained polymer was reprecipitated with hexane, thereby obtaining a perfluoroolefin copolymer (1) (19 g). The refractive index of the obtained polymer was 1.422.

(Preparation of Sol Liquid a)

Methyl ethyl ketone (120 parts by mass), acryloyloxypropyltrimethoxysilane (KBM-5103, manufactured by Shin-Etsu Chemical Co., Ltd.) (100 parts by mass), and diisopropoxyaluminum ethyl acetoacetate (trade name: CHELOPE EP-12, manufactured by Hope Chemical Co., Ltd.) (3 parts by mass) were added to a reactor provided with a stirrer and a reflux condenser and mixed. Thereafter, ion exchange water (31 parts by mass) was further added to the mixture, and the obtained solution was allowed to react at 61° C. for 4 hours and cooled to room temperature, thereby obtaining a sol liquid a.

The mass average molecular weight of the compound in the obtained sol liquid a was 1620, and the proportion of the components having a molecular weight of 1000 to 20000 in the oligomer component or higher components was 100%. Further, based on the gas chromatography analysis, acryloyloxypropyltrimethoxysilane as a raw material did not remain at all.

(Preparation of Hollow Silica Particle Dispersion Liquid)

A hollow silica particle sol (isopropyl alcohol silica sol, CS60-IPA, manufactured by JGC Catalysts & Chemicals, Ltd., average particle diameter: 60 nm, shell thickness: 10 nm, silica concentration: 20%, refractive index of silica particles: 1.31) (500 parts by mass), acryloyloxypropyltrimethoxysilane (30.5 parts by mass), and diisopropoxyaluminum ethyl acetate (1.51 parts by mass) were mixed, and ion exchanged water (9 parts by mass) was further added thereto.

Next, the obtained solution was allowed to react at 60° C. for 8 hours and cooled to room temperature, and acetylacetone (1.8 parts by mass) was added thereto, thereby obtaining a dispersion liquid. Thereafter, solvent substitution was performed by distillation under reduced pressure at a pressure of 30 Torr while cyclohexanone was added to the dispersion liquid so that the silica content was substantially constant, and the concentration thereof was adjusted, thereby obtaining a hollow silica particle dispersion liquid having a solid content concentration of 18.2% by mass. The residual amount of isopropyl alcohol (IPA) in the obtained dispersion liquid was analyzed by gas chromatography, and the amount was 0.5% or less.

The following composition was mixed using the obtained hollow silica particle dispersion liquid and the sol liquid a, and the obtained solution was stirred and filtered through a polypropylene filter having a pore size of 1 μm, thereby preparing a composition for forming a low refractive index layer.

(Composition of Composition for Forming Low Refractive Index Layer)
DPHA: 14.5 g
PO-1: 24.5 g
Hollow silica particle dispersion liquid: 302.2 g
RMS-033: 5.0 g
IRGACURE 907: 1.0 g
Methyl ethyl ketone: 1750 g
Cyclohexanone: 223.0 g

The compounds used in the above-described composition for forming a low refractive index layer are as follows.
PO-1: perfluoroolefin copolymer (1)
DPHA: mixture of dipentaerythritol pentaacrylate and dipentaerythritol hexaacrylate (manufactured by Nippon Kayaku Co., Ltd.)
RMS-033: reactive silicone (manufactured by Gelest, Inc.)
IRGACURE 907: photopolymerization initiator (manufactured by BASF SE)

(Preparation of Hard Coat Layer)

A support 51 (TAC base material having a thickness of 40 μm; TG40, FUJIFILM Corporation) was coated with a composition for forming a hard coat layer using a gravure coater. The coating film was dried at 100° C., irradiated with ultraviolet rays at an illuminance of 400 mW/cm² with an irradiation amount of 150 mJ/cm² using an air-cooled metal halide lamp (manufactured by Eye Graphics Co., Ltd.) at 160 W/cm while nitrogen was purged such that an atmosphere with an oxygen concentration of 1.0% by volume or less was obtained, and cured, thereby forming a hard coat layer having a thickness of 12 μm. The refractive index was 1.52.

The obtained hard coat layer was coated with the composition for forming a medium refractive index layer, the composition for forming a high refractive index layer, and the composition for forming a low refractive index layer, each of which was adjusted to have a desired refractive index, using a gravure coater, thereby preparing an antireflection film.

Further, the refractive index of each layer was measured by coating a glass plate with the composition for forming each layer such that the thickness thereof was approximately 4 μm, using a multi-wavelength Abbe refractometer DR-M2 (manufactured by Atago Co., Ltd.).

In addition, the refractive index measured using the filter of “Interference filter for DR-M2 and M4, 546 (e) nm, component No.: RE-3523” was employed as a refractive index at a wavelength of 550 nm.

The film thickness of each layer was calculated using a reflection spectroscopic film thickness meter “FE-3000” (manufactured by Otsuka Electronics Co., Ltd.) after laminating the medium refractive index layer, the high refractive index layer, and the low refractive index layer in this order. As the refractive index of each layer in the calculation, the value derived by the above-described Abbe refractive index meter was used.

The medium refractive index layer was irradiated with ultraviolet rays at an illuminance of 300 mW/cm² with an irradiation amount of 240 mJ/cm² using an air-cooled metal halide lamp (manufactured by Eye Graphics Co., Ltd.) at 180 W/cm while nitrogen was purged to have an atmosphere in which the medium refractive index layer was dried at 90° C. for 30 seconds and cured by ultraviolet rays with an oxygen concentration of 1.0% by volume.

The refractive index of the cured medium refractive index layer was 1.62, and the layer thickness thereof was 60 nm.

The high refractive index layer was irradiated with ultraviolet rays at an illuminance of 300 mW/cm² with an irradiation amount of 240 mJ/cm² using an air-cooled metal halide lamp (manufactured by Eye Graphics Co., Ltd.) at 240 W/cm while nitrogen was purged to have an atmosphere in which the high refractive index layer was dried at 90° C. for 30 seconds and cured by ultraviolet rays with an oxygen concentration of 1.0% by volume. The refractive index of the cured high refractive index layer was 1.72, and the layer thickness thereof was 110 nm.

The low refractive index layer was irradiated with ultraviolet rays at an illuminance of 600 mW/cm² with an irradiation amount of 600 mJ/cm² using an air-cooled metal halide lamp (manufactured by Eye Graphics Co., Ltd.) at 240 W/cm while nitrogen was purged to have an atmosphere in which the low refractive index layer was dried at 90° C. for 30 seconds and cured by ultraviolet rays with an oxygen concentration of 0.1% by volume. The refractive index of the cured low refractive index layer was 1.36, and the layer thickness thereof was 90 nm.

In this manner, a surface protective layer H1 was prepared.

<Preparation of Laminate of Example 1>

The laminated film 1B on the oxygen blocking layer B1 side was bonded to the surface protective layer H1 on the support side using a pressure sensitive adhesive sheet (SK2057, manufactured by Soken Chemical Co., Ltd.) as the pressure sensitive adhesive layer 1. Further, the cellulose acylate film 1 and the photo-alignment layer PA1 were removed, and the surface after removal and the pressure sensitive adhesive sheet serving as the pressure sensitive adhesive layer 2 were bonded to each other, thereby forming a laminate 1 of Example 1.

Further, the laminate 1 had a layer configuration of the surface protective layer H1, the pressure sensitive adhesive layer 1, the oxygen blocking layer B1, the cured layer N1, the light absorption anisotropic layer P1, the first optically anisotropic layer 1, and the pressure sensitive adhesive layer 2.

### Example 2

A laminate was prepared in the same manner as in Example 1 except that the first optically anisotropic layer 2 was formed of the following polymerizable liquid crystal compound C (80 parts by mass) and the following polymerizable liquid crystal compound D (20 parts by mass) in place of the polymerizable liquid crystal compound A (65 parts by mass) and the polymerizable liquid crystal compound B (35 parts by mass) used for forming the first optically anisotropic layer, thereby obtaining a laminate 2 of Example 2.

Here, it was confirmed that the formed first optically anisotropic layer 2 was a positive A-plate that did not satisfy Expression (I), and a photo-aligned group derived from the cleavage group-containing photo-aligned polymer FP-1 was unevenly distributed on a side opposite to the photo-alignment layer PA-1 (air interface side) similarly to the first optically anisotropic layer 1. The film thickness of the first optically anisotropic layer 2 was 2.5 μm.

Further, the laminate 2 had a layer configuration of the surface protective layer H1, the pressure sensitive adhesive layer 1, the oxygen blocking layer B1, the cured layer N1, the light absorption anisotropic layer P1, the first optically anisotropic layer 2, and the pressure sensitive adhesive layer 2.

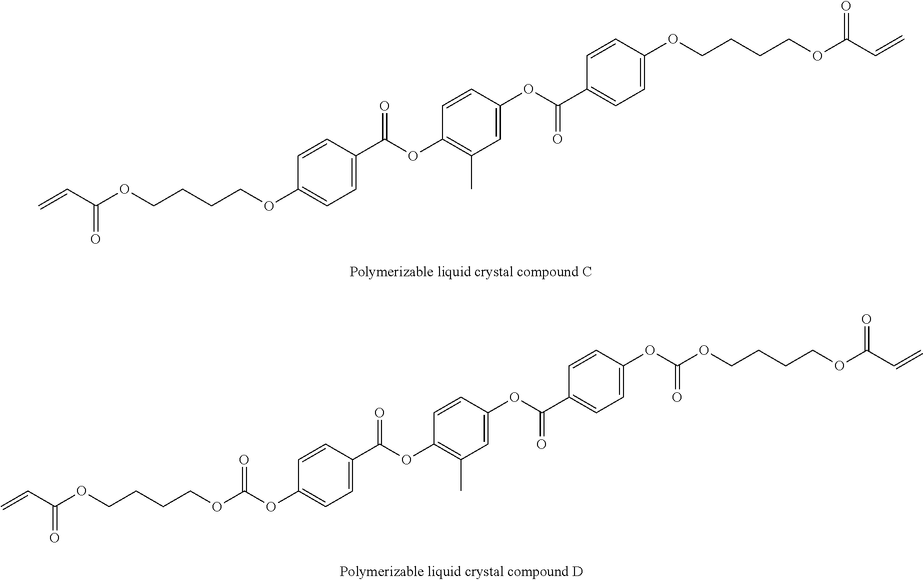

### Example 3

A laminate was prepared in the same manner as in Example 1 except that the following second optically anisotropic layer 1 was used in place of the cellulose acylate film 1 and the photo-alignment layer PA-1 and was not removed, thereby obtaining a laminate 3 of Example 3.

Further, the laminate 3 had a layer configuration of the surface protective layer H1, the pressure sensitive adhesive layer 1, the oxygen blocking layer B1, the cured layer N1, the light absorption anisotropic layer P1, the first optically anisotropic layer 1, the second optically anisotropic layer 1, and the pressure sensitive adhesive layer 2.

<Formation of Second Optically Anisotropic Layer>

The polymerizable liquid crystal compound C (83 parts by mass), the polymerizable liquid crystal compound E (15 parts by mass), the polymerizable liquid crystal compound F (2 parts by mass), an acrylate monomer (A-400, manufactured by Shin Nakamura Chemical Industry Co., Ltd.) (4 parts by mass), the following hydrophilic polymer (2 parts by mass), the following vertical alignment agent A (2 parts by mass), the following photopolymerization initiator B-2 (4 parts by mass), the following photoacid generator (B-3) (3 parts by mass), and the cleavage group-containing photo-aligned polymer FP-1 (3.0 parts by mass) were dissolved in 680 parts by mass of methyl isobutyl ketone, thereby preparing a solution for forming a liquid crystal layer.

A cellulose-based polymer film (TG40, manufactured by FUJIFILM Corporation) was coated with the prepared solution for forming a liquid crystal layer using a #3.0 wire bar, heated at 70° C. for 2 minutes, and irradiated with ultraviolet rays with an irradiation amount of 200 mJ/cm² using a 365 nm UV-LED while nitrogen was purged to have an atmosphere in which the oxygen concentration was 100 ppm or less. Thereafter, the film was annealed at 120° C. for 1 minute, thereby forming a second optically anisotropic layer 1.

The Film Thickness Thereof was Approximately 0.5 μm.

Further, it was confirmed that the formed second optically anisotropic layer was a positive C-plate and a photo-aligned group derived from the cleavage group-containing photo-aligned polymer FP-1 was unevenly distributed on a side opposite to the cellulose-based polymer film (air interface side).

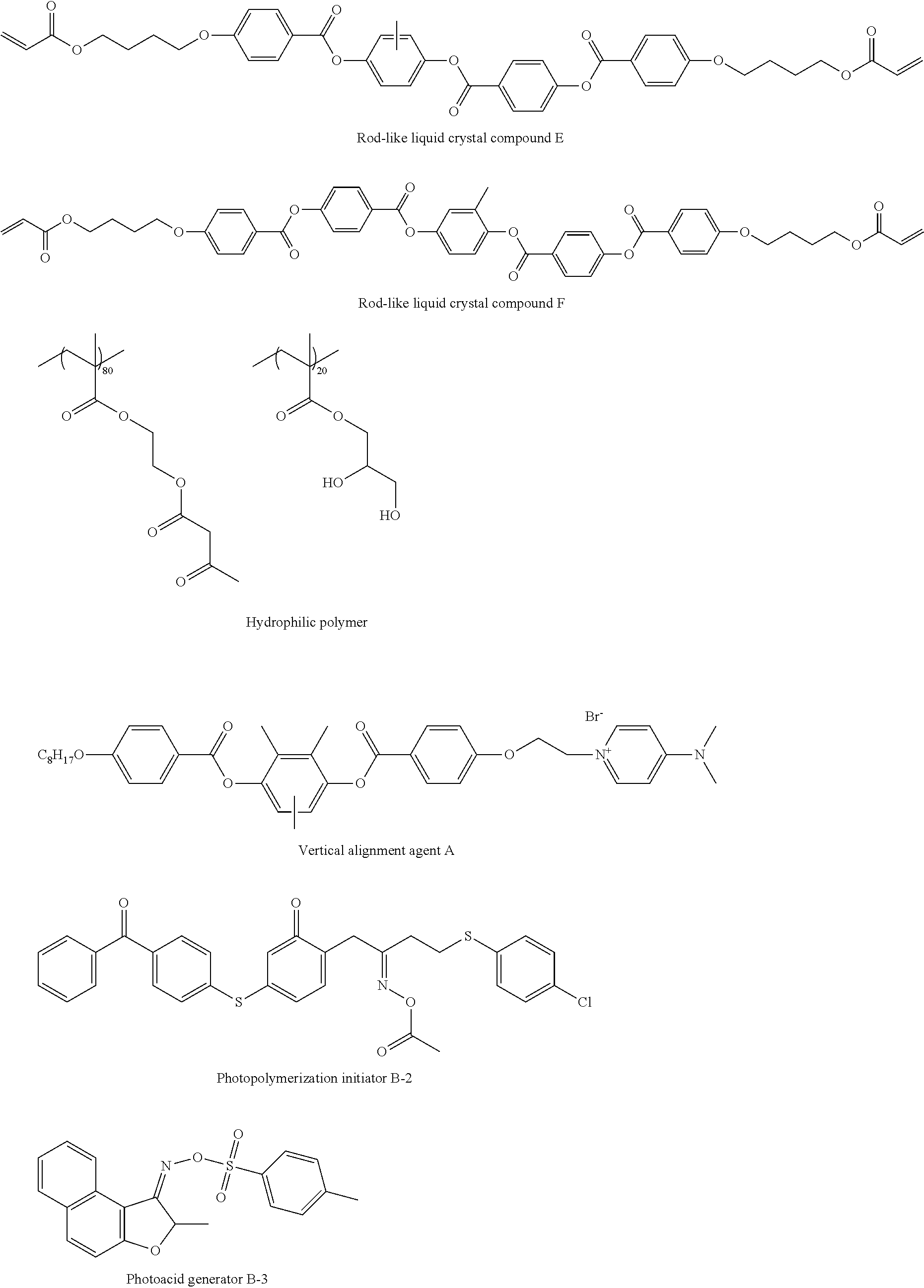

<Irradiation Step (Impartment of Alignment Function)>

The obtained second optically anisotropic layer was irradiated with UV light (ultra-high pressure mercury lamp; UL750; manufactured by HOYA Corporation) having passed through a wire grid polarizer at room temperature with an irradiation amount of 7.9 mJ/cm² (wavelength: 313 nm), and an alignment function was imparted to the layer.

### Example 4

A laminate was prepared in the same manner as in Example 1 except that a first optically anisotropic layer 3 was formed by adding 1 part by mass of the following interlayer alignment agent in place of the cleavage group-containing photo-aligned polymer FP-1 used for forming the first optically anisotropic layer, irradiating the layer with ultraviolet rays with an irradiation amount of 100 mJ/cm² using a UV-LED (wavelength of 365 nm) without purging nitrogen, and performing a rubbing treatment without irradiating the layer with polarized ultraviolet rays, thereby obtaining a laminate 4 of Example 4.

Here, it was confirmed that the formed first optically anisotropic layer 3 was a positive A-plate satisfying Expression (I). The film thickness of the first optically anisotropic layer 3 was 2.5 μm.

Further, the laminate 4 had a layer configuration of the surface protective layer H1, the pressure sensitive adhesive layer 1, the oxygen blocking layer B1, the cured layer N1, the light absorption anisotropic layer P1, the first optically anisotropic layer 3, and the pressure sensitive adhesive layer 2.

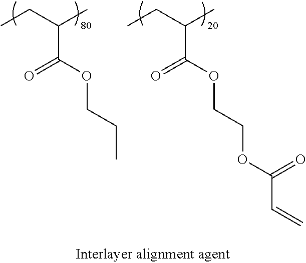

### Comparative Example 1

<Formation of Photo-Alignment Layer PA2>

The cellulose acylate film 1 was continuously coated with the following coating solution PA2 for forming an alignment layer using a wire bar. The support on which the coating film was formed was dried with hot air at 140° C. for 120 seconds, and the coating film was irradiated with polarized ultraviolet rays (10 mJ/cm², using an ultra-high pressure mercury lamp) to form a photo-alignment layer PA2, thereby obtaining a TAC film provided with a photo-alignment layer.

The film thickness of the photo-alignment layer PA2 was 1.0 μm.
(Coating Solution PA2 for Forming Alignment Layer)
Polymer PA-2 shown below: 100.00 parts by mass
Acid generator TAG-2 shown below: 5.00 parts by mass
Acid generator CPI-110TF shown below: 0.005 parts by mass
Xylene: 1220.00 parts by mass
Methyl isobutyl ketone: 122.00 parts by mass

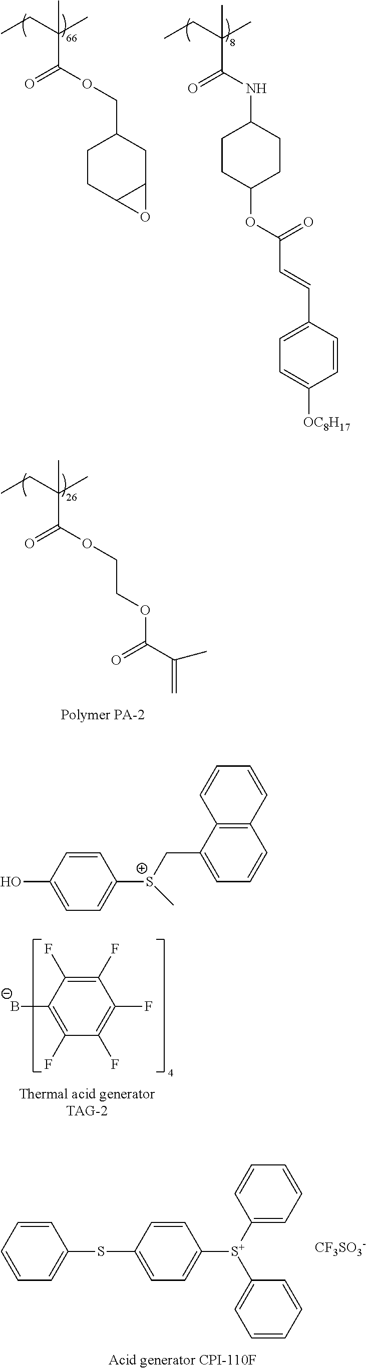

<Formation of Light Absorption Anisotropic Layer P2>

A light absorption anisotropic layer P2 was prepared by coating the obtained photo-alignment layer PA2 with the composition P1 for forming a light absorption anisotropic layer in the same manner as in Example 1.

The film thickness of the light absorption anisotropic layer P2 was 0.4 μm.

A laminated film 2B was prepared by forming the cured layer N1 and the oxygen blocking layer B1 on the light absorption anisotropic layer P2 in the same manner as in Example 1.

<Formation of First Optically Anisotropic Layer>

The polymerizable liquid crystal compound A (65 parts by mass), the polymerizable liquid crystal compound B (35 parts by mass), a photopolymerization initiator (IRGACURE 907, manufactured by BASF SE) (3 parts by mass), a sensitizer (KAYACURE DETX, manufactured by Nippon Kayaku Co., Ltd.) (1 part by mass), the horizontal alignment agent (0.3 parts by mass), and the photoacid generator (B-1-1) (3.0 parts by mass) were dissolved in cyclopentanone (193 parts by mass), thereby preparing a solution for forming an optically anisotropic layer.

The photo-alignment layer PA-1 the TAC film provided with a photo-alignment layer used in Example 1 was coated with the above-described solution for forming an optically anisotropic layer using a #7 wire bar coater, heated at 60° C. for 2 minutes, and irradiated with ultraviolet rays at an irradiation amount of 100 mJ/cm² using a UV-LED (wavelength of 365 nm) while the state of the layer was maintained at 60° and nitrogen was purged to have an atmosphere with an oxygen concentration of 1.0% by volume or less, to form a first optically anisotropic layer 4, thereby obtaining a first optically anisotropic film 4.

Here, it was confirmed that the formed first optically anisotropic layer 4 was a positive A-plate satisfying Expression (I). The film thickness of the first optically anisotropic layer 4 was 2.5 μm.

### Preparation of Laminate of Comparative Example 1

The laminated film 2B on the oxygen blocking layer side was bonded to the surface protective layer H1 on the support side used in Example 1 with a pressure sensitive adhesive sheet as the pressure sensitive adhesive layer 1. Further, only the cellulose acylate film 1 was removed, and the first optically anisotropic film 4 on the optically anisotropic layer side was bonded to the surface after removal using the pressure sensitive adhesive sheet as the pressure sensitive adhesive layer 2. Further, the cellulose acylate film 1 including the photo-alignment layer PA1 was removed, and the pressure sensitive adhesive sheet was bonded to the surface after removal as the pressure sensitive adhesive layer 3, thereby obtaining a laminate 5 of Comparative Example 1.

Further, the laminate 5 had a layer configuration of the surface protective layer H1, the pressure sensitive adhesive layer 1, the oxygen blocking layer B1, the cured layer N1, the light absorption anisotropic layer P2, the photo-alignment layer PA2, the pressure sensitive adhesive layer 2, the first optically anisotropic layer 4, and the pressure sensitive adhesive layer 3.

[Antireflection Performance]

The antireflection performance of each of the obtained laminates was evaluated.

Specifically, the laminate on the pressure sensitive adhesive layer 2 side or the pressure sensitive adhesive layer 3 side was bonded to an aluminum substrate, the surface state was visually observed, and the antireflection performance was evaluated according to the following evaluation standards. Further, the surface reflectance of the prepared aluminum substrate was 84%.
A: The surface was black without coloration in the front direction and in an oblique direction
B: The surface was black without coloration in the front direction, but the surface appeared to be colored in an oblique direction
C: The surface appeared to be colored even in the front direction

The results are listed in Table 1. Practically, A or B is preferable, and A is more preferable.

[Moisture-Heat Resistance]

The durability of each of the obtained optical laminates was evaluated.

Specifically, the laminate on the pressure sensitive adhesive layer 2 side or the pressure sensitive adhesive layer 3 side was bonded to an aluminum substrate in the same manner as described above, allowed to stand in a thermohygrostat at 60° C. and 90% RH for 65 hours, and taken out, the surface state was visually observed, and the moisture-heat resistance was evaluated according to the following evaluation standards.
A: Reflection unevenness was not found after the aluminum plate was put in the thermohygrostat.
B: Reflection unevenness was slightly found after the aluminum plate was put in the thermohygrostat.
C: Reflection unevenness was significantly found after the aluminum plate was put in the thermohygrostat.

The results are listed in Table 1. Practically, A or B is preferable, and A is more preferable.

TABLE 1

| | Ex- | Ex- | Ex- | Ex- | Comparative |
|---|---|---|---|---|---|
| | ample 1 | ample 2 | ample 3 | ample 4 | Example 1 |
| Antireflection | B | C | A | C | B |
| performance | | | | | |
| Moisture-heat | A | A | A | A | C |
| resistance | | | | | |

As shown in the results listed in Table 1, it was found that the laminate obtained by laminating a light absorption anisotropic layer and an optically anisotropic layer via a pressure sensitive adhesive layer had poor moisture-heat resistance (Comparative Example 1).

On the contrary, it was found that the laminate obtained by directly laminating a light absorption anisotropic layer containing an organic dichroic substance and an optically anisotropic layer consisting of a liquid crystal layer had excellent moisture-heat resistance (Examples 1 to 4).

Further, based on the comparison between Examples 1 and 2, it was found that in a case where the optically anisotropic layer satisfied Expression (I), the antireflection performance in a case bonding the layer to a substrate was excellent.

Further, based on the comparison between Examples 1 and 3, it was found that the antireflection performance was further improved by providing the second optically anisotropic layer.

Further, based on the comparison between Examples 1 and 4, it was found that the antireflection performance was more excellent in a case where a photo-aligned group was unevenly distributed in the light absorption anisotropic layer on an interface side with the first optically anisotropic layer using the cleavage group-containing photo-aligned polymer during the formation of the first optically anisotropic layer rather than a case where the first optically anisotropic layer was subjected to a rubbing treatment.

What is claimed is:

1. A laminate comprising:
a light absorption anisotropic layer; and
an optically anisotropic layer,
wherein the light absorption anisotropic layer contains an organic dichroic substance,
the optically anisotropic layer consists of a liquid crystal layer with molecules of a liquid crystal compound being fixed in a state of a smectic phase or a nematic phase in homogeneous alignment,
a photo-aligned polymer contained in the optically anisotropic layer does not contain a fluorine atom or a silicon atom,
an axial direction of an absorption axis of the light absorption anisotropic layer is different from an axial direction of a slow axis of the optically anisotropic layer, and
the light absorption anisotropic layer and the optically anisotropic layer are directly laminated.

2. The laminate according to claim 1,
wherein the optically anisotropic layer satisfies Expression (I),
0.50<Re(450)/Re(550)<1.00 (I)
in Expression (I), Re (450) represents an in-plane retardation of the optically anisotropic layer at a wavelength of 450 nm, and Re (550) represents an in-plane retardation of the optically anisotropic layer at a wavelength of 550 nm.

3. The laminate according to claim 1,
wherein the optically anisotropic layer is a layer formed of a polymerizable liquid crystal composition containing a polymerizable liquid crystal compound exhibiting reverse wavelength dispersibility.

4. The laminate according to claim 1,
wherein a photo-aligned group is unevenly distributed in the light absorption anisotropic layer on an interface side with the optically anisotropic layer.

5. The laminate according to claim 1,
wherein the optically anisotropic layer includes a first optically anisotropic layer and a second optically anisotropic layer, and
the light absorption anisotropic layer, the first optically anisotropic layer, and the second optically anisotropic layer are directly laminated in this order.

6. The laminate according to claim 5,
wherein the first optically anisotropic layer is a positive A-plate.

7. The laminate according to claim 5,
wherein the second optically anisotropic layer is a positive C-plate.

8. A laminate comprising:
a light absorption anisotropic layer; and
an optically anisotropic layer,
wherein the light absorption anisotropic layer contains an organic dichroic substance,
the optically anisotropic layer consists of a liquid crystal layer with molecules of a liquid crystal compound being fixed in a state of a smectic phase or a nematic phase in homogeneous alignment,
a photo-aligned polymer contained in the optically anisotropic layer does not contain a fluorine atom or a silicon atom,
a photo-aligned group is unevenly distributed in the light absorption anisotropic layer on an interface side with the optically anisotropic layer, and
the light absorption anisotropic layer and the optically anisotropic layer are directly laminated.

9. A polarizing plate comprising:
the laminate according to claim 1.

10. An image display device comprising:
the laminate according to claim 1.

11. The laminate according to claim 2,
wherein a photo-aligned group is unevenly distributed in the light absorption anisotropic layer on an interface side with the optically anisotropic layer.
